(19) United States
(12) Patent Application Publication
(10) Pub. No.: US 2025/0096207 A1
(43) Pub. Date: Mar. 20, 2025

(54) PACKAGE COMPRISING A BRIDGE LOCATED BETWEEN METALLIZATION PORTIONS

(71) Applicant: QUALCOMM Incorporated, San Diego, CA (US)

(72) Inventors: Yue LI, San Diego, CA (US); Durodami LISK, San Diego, CA (US); Ryan LANE, San Diego, CA (US); Darko POPOVIC, San Diego, CA (US)

(21) Appl. No.: 18/470,344

(22) Filed: Sep. 19, 2023

(51) Int. Cl. H01L 25/10; H01L 23/00; H01L 23/31; H01L 23/498; H01L 23/538

(52) U.S. Cl. CPC H01L 25/105; H01L 23/3128; H01L 23/49811; H01L 23/5381; H01L 23/5383; H01L 23/5385; H01L 24/08; H01L 24/16; H01L 2224/08225; H01L 2224/16227

(57) ABSTRACT

A package comprising a first metallization portion; a first integrated device coupled to the first metallization portion; a bridge coupled to the first metallization portion; an encapsulation layer coupled to the first metallization portion; a second metallization portion coupled to the bridge and the encapsulation layer, such that the first integrated device, the bridge and the encapsulation layer are located between the first metallization portion and the second metallization portion, and a second integrated device coupled to the second metallization portion, wherein the second integrated device and the bridge at least partially vertically overlap.

### FIELD

Various features relate to packages with metallization portions and integrated devices.

### BACKGROUND

A package may include a substrate and integrated devices. These components are coupled together to provide a package that may perform various electrical functions. There is an ongoing need to provide better performing packages and reduce the overall size of the packages.

### SUMMARY

Various features relate to packages with metallization portions and integrated devices.

One example provides a package comprising a first metallization portion comprising at least one first dielectric layer; and a first plurality of metallization interconnects; a first integrated device coupled to the first metallization portion; a bridge coupled to the first metallization portion; an encapsulation layer coupled to the first metallization portion; a second metallization portion coupled to the bridge and the encapsulation layer, such that the first integrated device, the bridge and the encapsulation layer are located between the first metallization portion and the second metallization portion, wherein the second metallization portion comprises: at least one second dielectric layer; and a second plurality of metallization interconnects; and a second integrated device coupled to the second metallization portion, wherein the second integrated device and the bridge at least partially vertically overlap.

Another example provides a package comprising a first metallization portion comprising: at least one first dielectric layer; and a first plurality of metallization interconnects; a first integrated device coupled to the first metallization portion through a least a first plurality of solder interconnects; a bridge coupled to the first metallization portion through at least a second plurality of solder interconnects; an encapsulation layer coupled to the first metallization portion; a second metallization portion coupled to the bridge and the encapsulation layer, such that the first integrated device, the bridge and the encapsulation layer are located between the first metallization portion and the second metallization portion, wherein the second metallization portion comprises at least one second dielectric layer; and a second plurality of metallization interconnects; and a second integrated device coupled to the second metallization portion through at least a third plurality of solder interconnects, wherein the second integrated device and the bridge at least partially vertically overlap.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a metallization portion and at least one bridge.

FIG. 2 illustrates an exemplary cross sectional profile view of a package that includes a metallization portion and at least one bridge.

FIG. 3 illustrates an exemplary cross sectional profile view of a package that includes a metallization portion and at least one bridge.

FIG. 4 illustrates an exemplary cross sectional profile view of a package that includes a metallization portion and at least one bridge.

FIG. 5 illustrates an exemplary cross sectional profile view of a package that includes a metallization portion and at least one bridge.

FIG. 6 illustrates an exemplary cross sectional profile view of a package that includes a metallization portion and at least one bridge.

FIG. 7 illustrates an exemplary plan view of a package that includes a bridge.

FIG. 8 illustrates an exemplary plan view of a package that includes a bridge.

FIG. 9 illustrates an exemplary plan view of a package that includes a bridge.

FIG. 10 illustrates an exemplary plan view of a package that includes a bridge.

FIGS. 11A-11D illustrate an exemplary sequence for fabricating a package that includes metallization portions and a bridge.

FIGS. 12A-12E illustrate an exemplary sequence for fabricating a package that includes metallization portions and a bridge.

FIGS. 13A-13C illustrate an exemplary sequence for fabricating a package that includes metallization portions and a bridge.

FIG. 14 illustrates an exemplary flow chart of a method for fabricating a package that includes metallization portions and a bridge.

FIGS. 15A-15D illustrate an exemplary sequence for fabricating a package that includes metallization portions and a bridge.

FIGS. 16A-16F illustrate an exemplary sequence for fabricating a package that includes metallization portions and a bridge.

FIGS. 17A-17D illustrate an exemplary sequence for fabricating a package that includes metallization portions and a bridge.

FIG. 18 illustrates an exemplary flow chart of a method for fabricating a package that includes metallization portions and a bridge.

FIG. 19A-19B illustrate an exemplary sequence for fabricating a metallization portion.

FIG. 20 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising a first metallization portion comprising at least one first dielectric layer; and a first plurality of metallization interconnects; a first integrated device coupled to the first metallization portion; a bridge coupled to the first metallization portion; an encapsulation layer coupled to the first metallization portion; a second metallization portion coupled to the bridge and the encapsulation layer, such that the first integrated device, the bridge and the encapsulation layer are located between the first metallization portion and the second metallization portion, wherein the second metallization portion comprises: at least one second dielectric layer; and a second plurality of metallization interconnects; and a second integrated device coupled to the second metallization portion, wherein the second integrated device and the bridge at least partially vertically overlap. As will be further described below, the package provides interconnects with high aspect ratios and high density interconnection, which helps provide improved package performance, while keeping the package small and thin.

### Exemplary Packages Comprising an Bridge

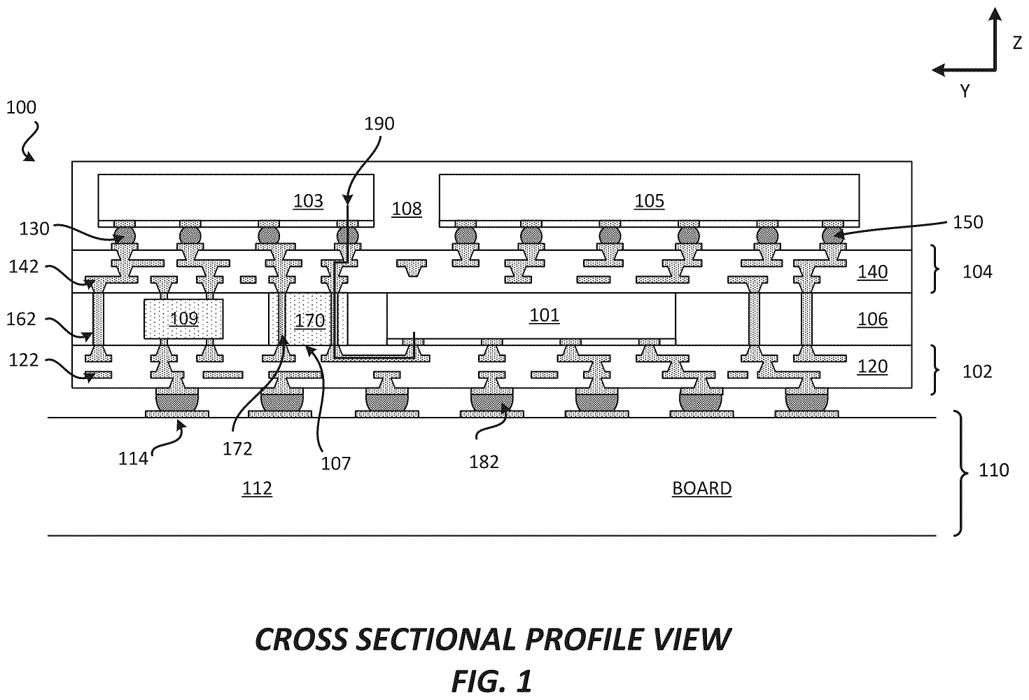

FIG. 1 illustrates a cross sectional profile view of a package 100 that includes metallization portions and a bridge. The package 100 is coupled to a board 110 through a plurality of solder interconnects 182. The board 110 includes at least one board dielectric layer 112 and a plurality of board interconnects 114. The board 110 may include a printed circuit board (PCB). The package 100 is coupled to the plurality of board interconnects 114 of the board 110 through the plurality of solder interconnects 182.

The package 100 includes an integrated device 101, a metallization portion 102, a metallization portion 104, an integrated device 103, an integrated device 105, bridge 107, a passive component 109, an encapsulation layer 106 and an encapsulation layer 108. The metallization portion 102 includes at least one dielectric layer 120 and a plurality of metallization interconnects 122. The metallization portion 104 includes at least one dielectric layer 140 and a plurality of metallization interconnects 142. The metallization portion 102 and/or the metallization portion 104 may be a redistribution portion. The plurality of metallization interconnects 122 and/or the plurality of metallization interconnects 142 may be redistribution interconnects.

The integrated device 101 includes a front side and a back side. The back side may be opposite to the front side. The back side may include a die substrate. The front side may include die pad interconnects. The integrated device 101 may be coupled to the metallization portion 102, such that the front side of the integrated device 101 faces the metallization portion 102. The integrated device 101 may be coupled to and touch the metallization portion 102. For example, the pad interconnects of the integrated device 101 may be coupled to and touch metallization interconnects from the plurality of metallization interconnects 122 of the metallization portion 102.

The bridge 107 may be coupled to and touch the metallization portion 102. The bridge 107 may include a bridge substrate 170 (e.g., silicon substrate, silicon interposer, silicon layer) and a plurality of bridge interconnects 172. The plurality of bridge interconnects 172 may extend through a thickness of the bridge substrate 170. In some implementations, the plurality of bridge interconnects 172 may include bridge interconnects on surface of the bridge substrate 170. The plurality of bridge interconnects 172 may be coupled to and touch metallization interconnects from the plurality of metallization interconnects 122 of the metallization portion 102. The bridge 107 may be coupled to and touch the metallization portion 104. The plurality of bridge interconnects 172 may be coupled to and touch metallization interconnects from the plurality of metallization interconnects 142 of the metallization portion 104. The bridge 107 may include an interposer that includes interposer interconnects.

The passive component 109 may be coupled directly or indirectly to the metallization portion 102 and the metallization portion 104. In some implementations, one or more post interconnects may be used to couple the passive component 109 to the metallization portion 102 and/or the metallization portion 104.

The encapsulation layer 106 may at least partially encapsulate the integrated device 101, the bridge 107 and the passive component 109. The encapsulation layer 106 may be coupled to the metallization portion 102 and the metallization portion 104. For example, the encapsulation layer 106 may be coupled to a first surface (e.g., top surface) of the metallization portion 102 and a second surface (e.g., bottom surface) of the metallization portion 104. The encapsulation layer 106, the integrated device 101, the bridge 107 and the passive component 109 may be located between the metallization portion 102 and the metallization portion 104. The back side of the integrated device 101 may or may not touch a second surface (e.g., bottom surface) of the metallization portion 104. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

There is a plurality of post interconnects 162 located in the encapsulation layer 106. The plurality of post interconnects 162 may extend through the encapsulation layer 106. The plurality of post interconnects 162 may be coupled to and touch (i) metallization interconnects from the plurality of metallization interconnects 122 of the metallization portion 102, and (ii) metallization interconnects from the plurality of metallization interconnects 142 of the metallization portion 104. Two or more post interconnects from the plurality of post interconnects may have a pitch (e.g., post interconnect pitch). Two or more bridge interconnects from the plurality of bridge interconnects 172 may have a pitch (e.g., bridge interconnect pitch). The pitch of the plurality of post interconnects 162 may be different from a pitch from the plurality of bridge interconnects 172 of the bridge 107. In some implementations, the pitch (e.g., minimum pitch) of the plurality of bridge interconnects 172 may be less than the pitch (e.g., minimum pitch) of the plurality of post interconnects 162. In some implementations, the pitch (e.g., minimum pitch) of the plurality of bridge interconnects 172 may be about 2-10 times smaller than the pitch (e.g., minimum pitch) of the plurality of post interconnects 162. For example, if two or more post interconnects have a pitch of about 100 micrometers, two or more bridge interconnects may have a pitch of about 50 micrometers. It is noted that the above dimensions and/or relative dimensions are merely exemplary. In some implementations, the pitch of the plurality of post interconnects 162 and/or the pitch of the bridge interconnects 172 may be different than what is mentioned above. In some implementations, the plurality of post interconnects 162 may have different pitches between different post interconnects. In some implementations, the plurality of bridge interconnects 172 may have different pitches between different bridge interconnects.

The integrated device 103 may be coupled to a first surface (e.g., top surface) of the metallization portion 104 through a plurality of solder interconnects 130. The plurality of solder interconnects 130 may be coupled to pad interconnects of the integrated device 103 and metallization interconnects from the plurality of metallization interconnects 142 of the metallization portion 104.

The integrated device 105 is coupled to the first surface (e.g., top surface) of the metallization portion 104 through a plurality of solder interconnects 150. The plurality of solder interconnects 150 may be coupled to pad interconnects of the integrated device 105 and metallization interconnects from the plurality of metallization interconnects 142 of the metallization portion 104.

The encapsulation layer 108 may at least partially encapsulate the integrated device 103 and/or the integrated device 105. The encapsulation layer 108 may be coupled to the first surface of the metallization portion 104. The encapsulation layer 108 may include a mold, a resin and/or an epoxy. The encapsulation layer 106 may be a means for encapsulation. The encapsulation layer 108 may be provided by using a compression and transfer molding process, a sheet molding process, or a liquid molding process.

The bridge 107 is located in the package 100 such that the bridge 107 vertically overlaps (e.g., partial overlap, complete overlap) with the integrated device 103. The bridge 107 is configured to provide one or more electrical paths between the integrated device 101 and the integrated device 103. The bridge 107 enables short high density electrical paths between the integrated device 101 and the integrated device 103.

An electrical path 190 between the integrated device 103 and the integrated device 101 may include (i) a solder interconnect from the plurality of solder interconnects 130, (ii) metallization interconnects from the plurality of metallization interconnects 142 of the metallization portion 104, (iii) a bridge interconnect from the plurality of bridge interconnects 172 of the bridge 107, and (iv) metallization interconnects from the plurality of metallization interconnects 122 of the metallization portion 102. A part of the electrical path 190 between the metallization portion 104 and the integrated device 101 may be free of any solder interconnects. A part of the electrical path 190 between the metallization portion 102 and the integrated device 101 may be free of any solder interconnects. For example, the integrated device 101 may be coupled to a metallization interconnect from the metallization portion 102 without any intervening solder interconnect. Similarly, a part of the electrical path 190 between the metallization portion 102 and the bridge 107 may be free of any solder interconnects. For example, a bridge interconnect of the bridge 107 may be coupled to a metallization interconnect from the metallization portion 102 without any intervening solder interconnect.

In some implementations, the integrated device 101 may be a first chiplet and the integrated device 103 may be a second chiplet, or vice versa. Both the integrated device 101 and the integrated device 103 may be configured to perform high speed data and signal processing and transfer, between the integrated device 101 and the integrated device 103. The bridge 107 may be configured to enable such high speed data and signal transfers between the integrated device 101 and the integrated device 103.

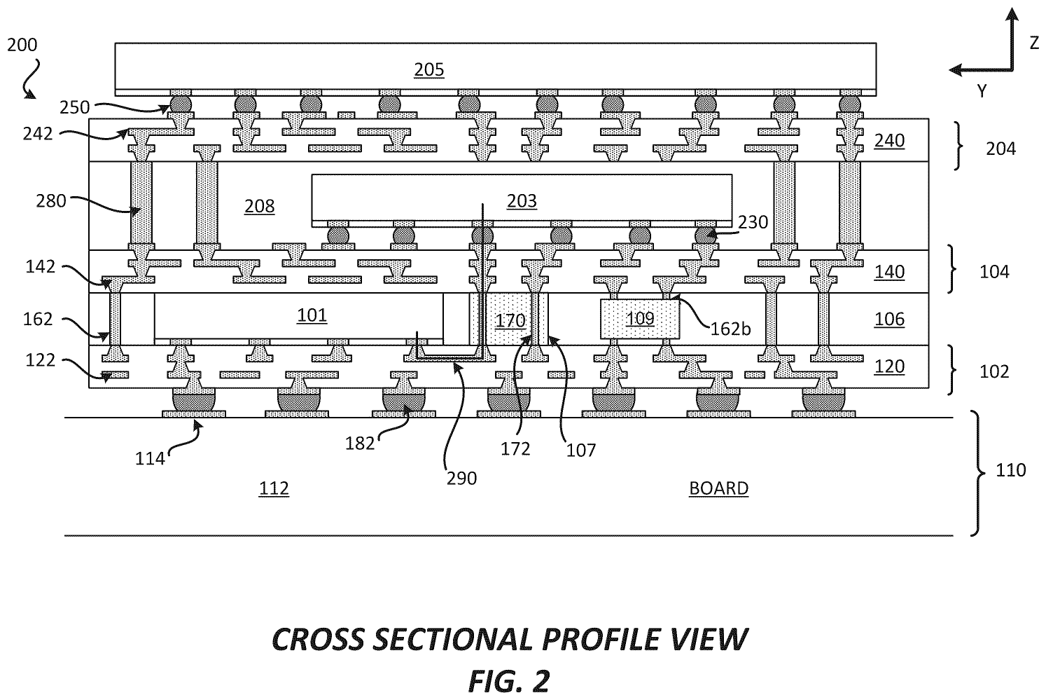

FIG. 2 illustrates a package 200 that includes metallization portions and a bridge. The package 200 is similar to the package 100, and includes similar and/or the same components as the package 100. The package 200 may be a package on package (POP). The package 200 is coupled to the plurality of board interconnects 114 of the board 110 through the plurality of solder interconnects 182. The package 200 includes three metallization portions.

The package 200 includes an integrated device 101, a metallization portion 102, a metallization portion 104, an integrated device 203, an integrated device 205, bridge 107, a passive component 109, an encapsulation layer 106, an encapsulation layer 108, and a metallization portion 204. The metallization portion 102 includes at least one dielectric layer 120 and a plurality of metallization interconnects 122. The metallization portion 104 includes at least one dielectric layer 140 and a plurality of metallization interconnects 142. The metallization portion 204 includes at least one dielectric layer 240 and a plurality of metallization interconnects 242. The metallization portion 102, the metallization portion 104 and/or the metallization portion 204 may be a redistribution portion. The plurality of metallization interconnects 122, the plurality of metallization interconnects 142 and/or the plurality of metallization interconnects 242 may be redistribution interconnects.

The integrated device 101, the bridge 107, the passive component 109 and the encapsulation layer 106 are located between the metallization portion 102 and the metallization portion 104. The front side of the integrated device 101 may be coupled to and touching a first surface (e.g., top surface) of the metallization portion 102. For example, pad interconnects of the integrated device 101 may be coupled to and touch metallization interconnects of the plurality of metallization interconnects 122 of the metallization portion 102. The bridge 107 may be coupled to and touch the metallization portion 102 and the metallization portion 104. For example, bridge interconnects from the plurality of bridge interconnects 172 may be coupled to and touch (i) metallization interconnects from the plurality of metallization interconnects 122 of the metallization portion 102 and (ii) metallization interconnects from the plurality of metallization interconnects 142 of the metallization portion 104.

The integrated device 203, the encapsulation layer 208 and the plurality of post interconnects 280 are located between the metallization portion 104 and the metallization portion 204. The integrated device 203 may be coupled to a first surface (e.g., top surface) of the metallization portion 104 through a plurality of solder interconnects 230. The plurality of post interconnects 280 may extend through the encapsulation layer 208. The plurality of post interconnects 280 may be coupled to and touching the metallization portion 104 and the metallization portion 204. The plurality of post interconnects 280 may be coupled to and touching the plurality of metallization interconnects 142 and the plurality of metallization interconnects 242. The encapsulation layer 208 may at least partially encapsulate the integrated device 203 and the plurality of post interconnects 280. The integrated device 203 may vertically overlap with the bridge 107 and the integrated device 101. The integrated device 205 may be coupled to the metallization portion 204 through a plurality of solder interconnects 250.

An electrical path 290 between the integrated device 203 and the integrated device 101 may include (i) a solder interconnect from the plurality of solder interconnects 230, (ii) metallization interconnects from the plurality of metallization interconnects 142 of the metallization portion 104, (iii) a bridge interconnect from the plurality of bridge interconnects 172 of the bridge 107, and (iv) metallization interconnects from the plurality of metallization interconnects 122 of the metallization portion 102. A part of the electrical path 290 between the metallization portion 104 and the integrated device 101 may be free of any solder interconnects. A part of the electrical path 290 between the metallization portion 102 and the integrated device 101 may be free of any solder interconnects. For example, the integrated device 101 may be coupled to a metallization interconnect from the metallization portion 102 without any intervening solder interconnect. Similarly, a part of the electrical path 290 between the metallization portion 102 and the bridge 107 may be free of any solder interconnects. For example, a bridge interconnect of the bridge 107 may be coupled to a metallization interconnect from the metallization portion 102 without any intervening solder interconnect.

In some implementations, the integrated device 101 may be a first chiplet and the integrated device 203 may be a second chiplet, or vice versa. Both the integrated device 101 and the integrated device 203 may be configured to perform high speed data and signal processing and transfer, between the integrated device 101 and the integrated device 203. The bridge 107 may be configured to enable such high speed data and signal transfers between the integrated device 101 and the integrated device 203.

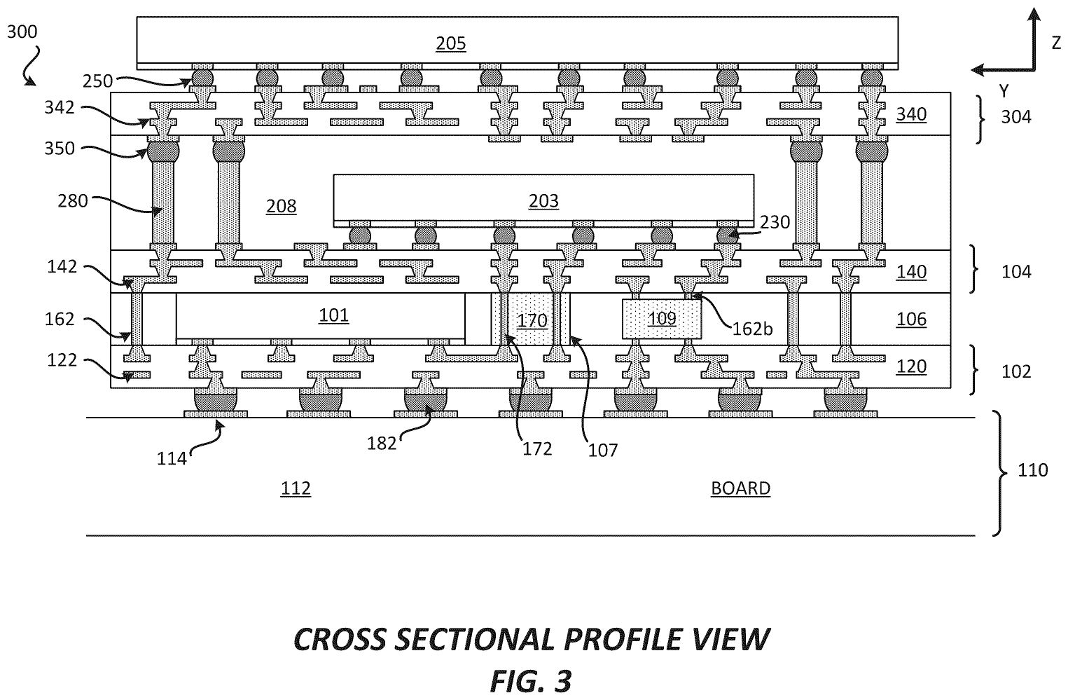

FIG. 3 illustrates a package 300 that includes metallization portions and a bridge. The package 300 is similar to the package 200 and the package 100, and includes similar and/or the same components as the package 200 and the package 100. The package 300 may be a package on package (POP). The package 300 is coupled to the plurality of board interconnects 114 of the board 110 through the plurality of solder interconnects 182. The package 300 includes two metallization portions and a substrate.

The package 300 includes an integrated device 101, a metallization portion 102, a metallization portion 104, an integrated device 203, an integrated device 205, bridge 107, a passive component 109, an encapsulation layer 106, an encapsulation layer 108, and a substrate 304. The metallization portion 102 includes at least one dielectric layer 120 and a plurality of metallization interconnects 122. The metallization portion 104 includes at least one dielectric layer 140 and a plurality of metallization interconnects 142. The substrate 302 includes at least one dielectric layer 340 and a plurality of interconnects 342. The metallization portion 102 and/or the metallization portion 104 may be a redistribution portion. The plurality of metallization interconnects 122 and/or the plurality of metallization interconnects 142 may be redistribution interconnects. The substrate 304 may be a laminate substrate.

Instead of a metallization portion 204, the package 300 includes the substrate 304. The integrated device 203, the plurality of post interconnects 280 and the encapsulation layer 208 are located between the metallization portion 104 and the substrate 304. The encapsulation layer 208 may be coupled to and touch the metallization portion 104 and the substrate 304. The plurality of post interconnects 280 are coupled to the substrate 304 through a plurality of solder interconnects 350. The plurality of solder interconnects 350 are coupled to and touching the plurality of post interconnects 280 and the plurality of interconnects 342 of the substrate 304. The integrated device 205 may be coupled to the substrate 304 through a plurality of solder interconnects 250.

An electrical path between the integrated device 203 and the integrated device 101 may be similar to the electrical path 290 described in FIG. 2.

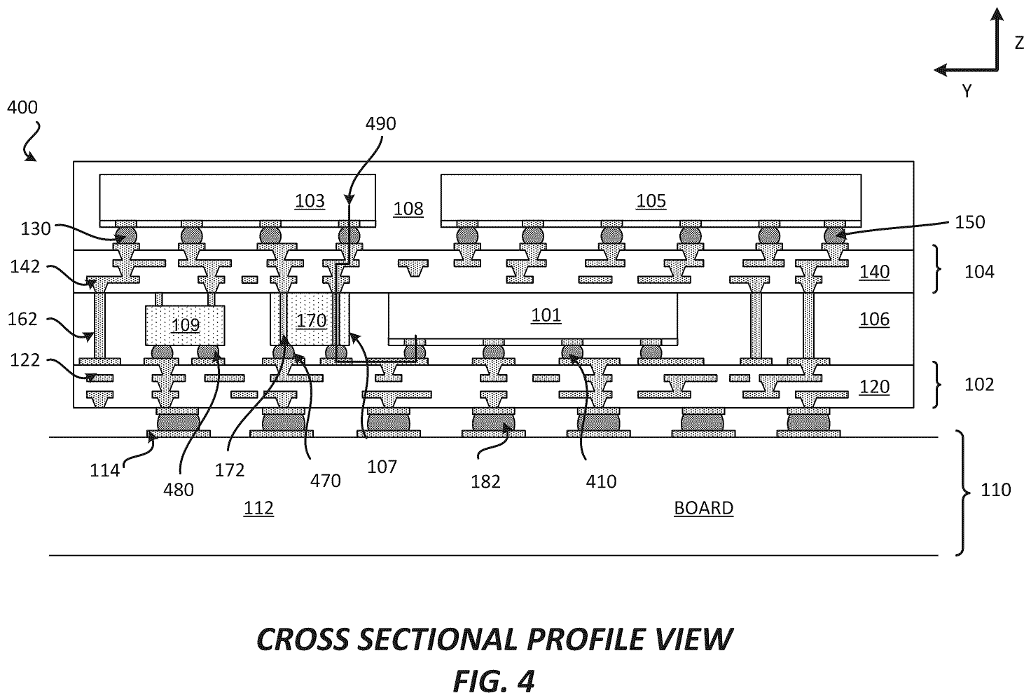

FIG. 4 illustrates a package 400 that includes metallization portions and a bridge. The package 400 is similar to the package 100, and includes similar and/or the same components as the package 100. The package 400 may be a package on package (POP). The package 400 is coupled to the plurality of board interconnects 114 of the board 110 through the plurality of solder interconnects 182. The package 400 includes two metallization portions.

The package 400 includes an integrated device 101, a metallization portion 102, a metallization portion 104, an integrated device 103, an integrated device 105, the bridge 107, a passive component 109, an encapsulation layer 106 and an encapsulation layer 108. The metallization portion 102 includes at least one dielectric layer 120 and a plurality of metallization interconnects 122. The front side of the integrated device 101 may be coupled to the metallization portion 102 through a plurality of solder interconnects 410. The bridge 107 may be coupled to the metallization portion 102 through a plurality of solder interconnects 470. The passive component 109 may be coupled to the metallization portion 102 through a plurality of solder interconnects 480.

The bridge 107 is located in the package 400 such that the bridge 107 vertically overlaps (e.g., partial overlap, complete overlap) with the integrated device 103. The bridge 107 is configured to provide one or more electrical paths between the integrated device 101 and the integrated device 103. The bridge 107 enables short high density electrical paths between the integrated device 101 and the integrated device 103.

An electrical path 490 between the integrated device 103 and the integrated device 101 may include (i) a solder interconnect from the plurality of solder interconnects 130, (ii) metallization interconnects from the plurality of metallization interconnects 142 of the metallization portion 104, (iii) a bridge interconnect from the plurality of bridge interconnects 172 of the bridge 107, (iv) a solder interconnect from the plurality of solder interconnects 470, (v) metallization interconnects from the plurality of metallization interconnects 122 of the metallization portion 102 and/or (vi) a solder interconnect from the plurality of solder interconnects 410.

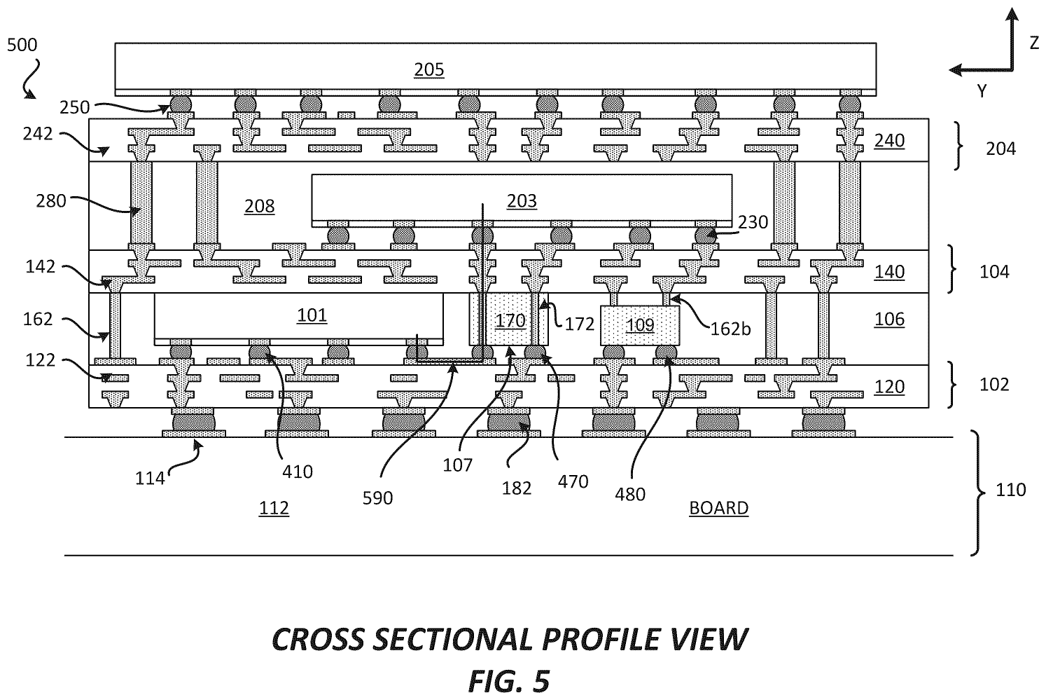

FIG. 5 illustrates a package 500 that includes metallization portions and a bridge. The package 500 is similar to the package 200, and includes similar and/or the same components as the package 200. The package 500 may be a package on package (POP). The package 500 is coupled to the plurality of board interconnects 114 of the board 110 through the plurality of solder interconnects 182. The package 500 includes three metallization portions.

The package 500 includes an integrated device 101, a metallization portion 102, a metallization portion 104, the metallization portion 204, an integrated device 203, an integrated device 205, the bridge 107, a passive component 109, an encapsulation layer 106 and an encapsulation layer 208. The front side of the integrated device 101 may be coupled to the metallization portion 102 through a plurality of solder interconnects 410. The bridge 107 may be coupled to the metallization portion 102 through a plurality of solder interconnects 470. The passive component 109 may be coupled to the metallization portion 102 through a plurality of solder interconnects 480.

The bridge 107 is located in the package 500 such that the bridge 107 vertically overlaps (e.g., partial overlap, complete overlap) with the integrated device 203. The bridge 107 is configured to provide one or more electrical paths between the integrated device 101 and the integrated device 203. The bridge 107 enables short high density electrical paths between the integrated device 101 and the integrated device 203.

An electrical path 590 between the integrated device 203 and the integrated device 101 may include (i) a solder interconnect from the plurality of solder interconnects 230, (ii) metallization interconnects from the plurality of metallization interconnects 142 of the metallization portion 104, (iii) a bridge interconnect from the plurality of bridge interconnects 172 of the bridge 107, (iv) a solder interconnect from the plurality of solder interconnects 470, (v) metallization interconnects from the plurality of metallization interconnects 122 of the metallization portion 102 and/or (vi) a solder interconnect from the plurality of solder interconnects 410.

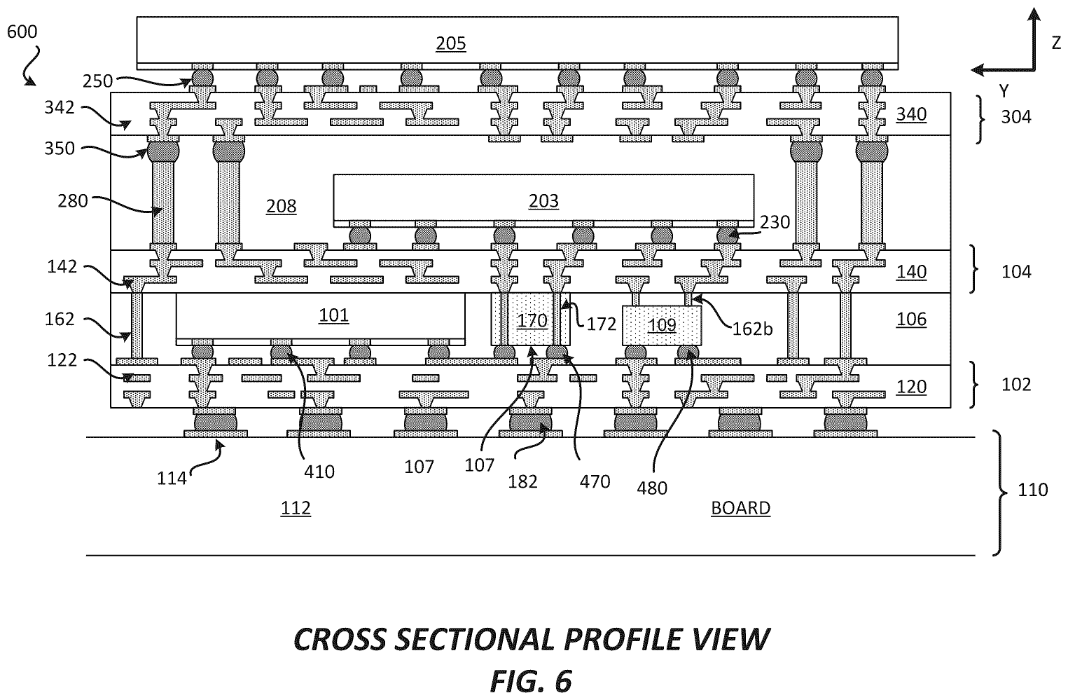

FIG. 6 illustrates a package 600 that includes metallization portions and a bridge. The package 600 is similar to the package 300, and includes similar and/or the same components as the package 300. The package 600 may be a package on package (POP). The package 600 is coupled to the plurality of board interconnects 114 of the board 110 through the plurality of solder interconnects 182. The package 600 includes two metallization portions and a substrate.

The package 600 includes an integrated device 101, a metallization portion 102, a metallization portion 104, the substrate 304, an integrated device 203, an integrated device 205, the bridge 107, a passive component 109, an encapsulation layer 106 and an encapsulation layer 208. The front side of the integrated device 101 may be coupled to the metallization portion 102 through a plurality of solder interconnects 410. The bridge 107 may be coupled to the metallization portion 102 through a plurality of solder interconnects 470. The passive component 109 may be coupled to the metallization portion 102 through a plurality of solder interconnects 480.

The bridge 107 is located in the package 600 such that the bridge 107 vertically overlaps (e.g., partial overlap, complete overlap) with the integrated device 203. The bridge 107 is configured to provide one or more electrical paths between the integrated device 101 and the integrated device 203. The bridge 107 enables short high density electrical paths between the integrated device 101 and the integrated device 203.

An electrical path between the integrated device 203 and the integrated device 101 may be similar and/or the same as the electrical path 590 described in FIG. 5.

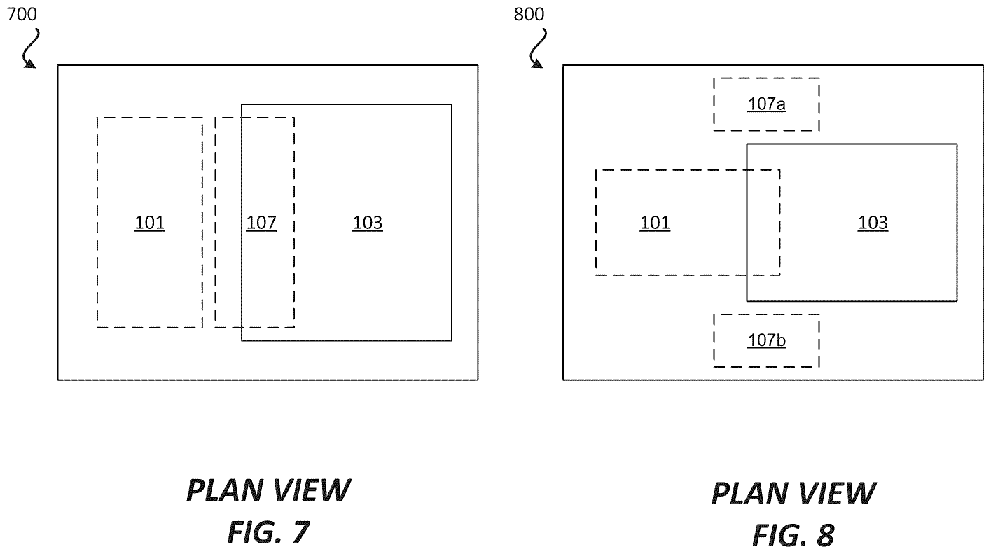

FIG. 7 illustrates a plan view of a package 700. The package 700 may represent any of the packages described in the disclosure. The package 700 includes the integrated device 101, the bridge 107 and the integrated device 103. Although not shown in FIG. 7, the package 700 may also include the integrated device 105. The bridge 107 is located laterally next to the integrated device 101. The bridge 107 at least partially vertically overlaps with the integrated device 103. In some implementations, the bridge 107 and/or the integrated device 101 may at least partially vertically overlap with the integrated device 105.

FIG. 8 illustrates a plan view of a package 800. The package 800 may represent any of the packages described in the disclosure. The package 800 includes the integrated device 101, the bridge 107a, the bridge 107b, and the integrated device 103. Although not shown in FIG. 7, the package 700 may also include the integrated device 105. The bridge 107a and the bridge 107b are located laterally next to the integrated device 101. The integrated device 101 at least partially vertically overlaps with the integrated device 103. In some implementations, the integrated device 101, the bridge 107a and/or the bridge 107b may at least partially vertically overlap with the integrated device 103.

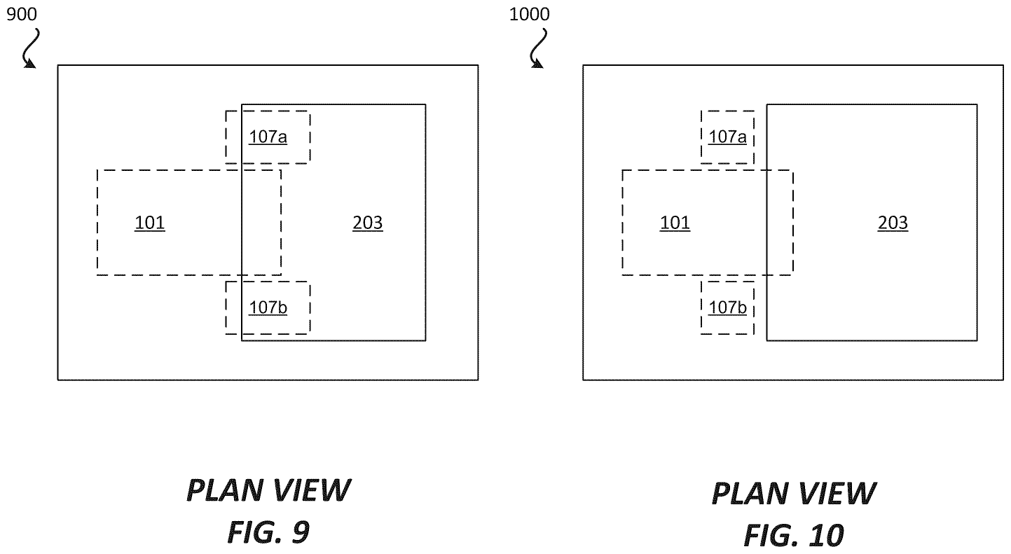

FIG. 9 illustrates a plan view of a package 900. The package 900 may represent any of the packages described in the disclosure. The package 900 includes the integrated device 101, the bridge 107a, the bridge 107b, and the integrated device 203. The bridge 107a and the bridge 107b are located laterally next to the integrated device 101. The integrated device 101 at least partially vertically overlaps with the integrated device 203. The bridge 107a and the bridge 107b at least partially vertically overlaps with the integrated device 203.

FIG. 10 illustrates a plan view of a package 1000. The package 1000 may represent any of the packages described in the disclosure. The package 1000 includes the integrated device 101, the bridge 107a, the bridge 107b, and the integrated device 203. The bridge 107a and the bridge 107b are located laterally next to the integrated device 101. The integrated device 101 at least partially vertically overlaps with the integrated device 203.

Different implementations may have different arrangements and/or configurations of integrated devices and/or bridges.

As mentioned above, a metallization portion (e.g., 102, 104) may include a redistribution portion that includes redistribution interconnects (e.g., redistribution layer (RDL) interconnects). A redistribution interconnect may include portions that have a U-shape or V-shape. The terms “U-shape” and “V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect).

An integrated device (e.g., 300, 400) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 100) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advance technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 200, 300, 400, 500, 600) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G, 6G). The packages (e.g., 100) may be configured to support Global System for Mobile (GSM) Communications, Universal Mobile Telecommunications System (UMTS), and/or Long-Term Evolution (LTE). The packages (e.g., 100, 200) may be configured to transmit and receive signals having different frequencies and/or communication protocols.

### Exemplary Sequence for Fabricating a Package Comprising a Bridge Between Metallization Portions

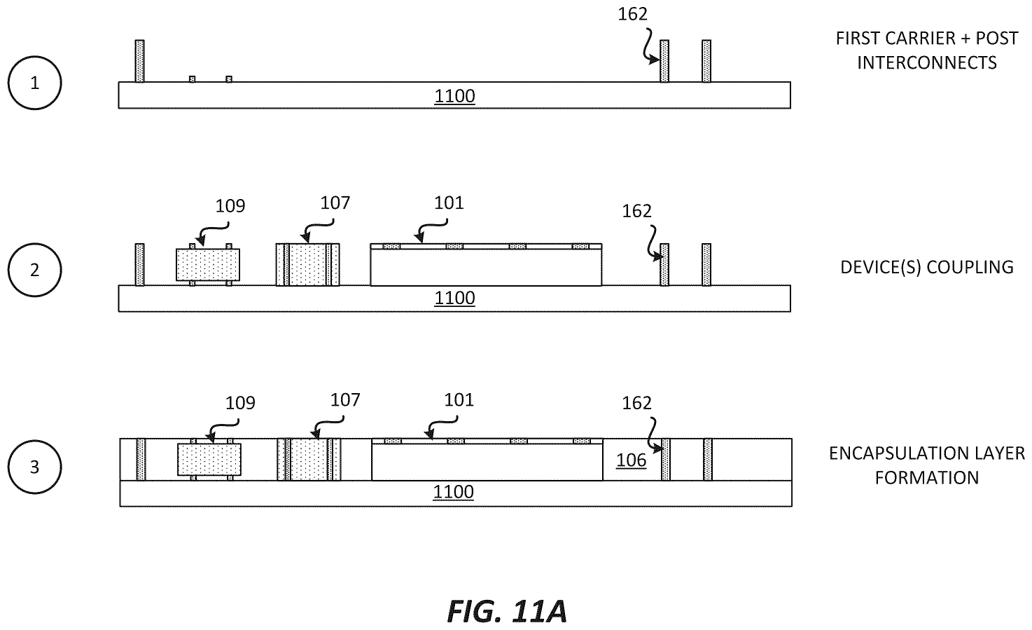

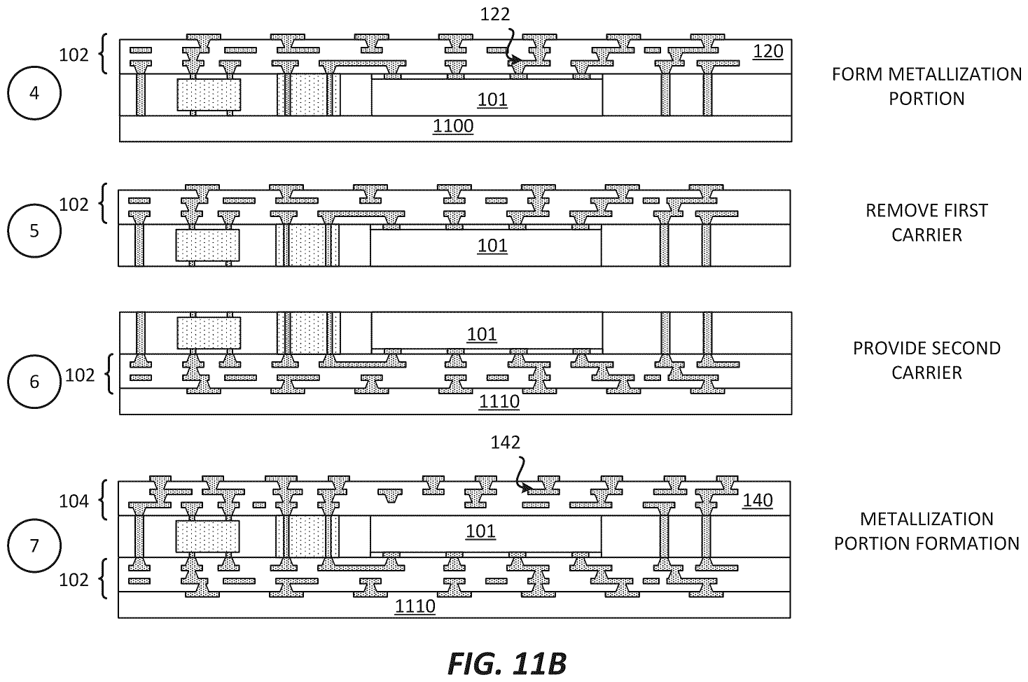

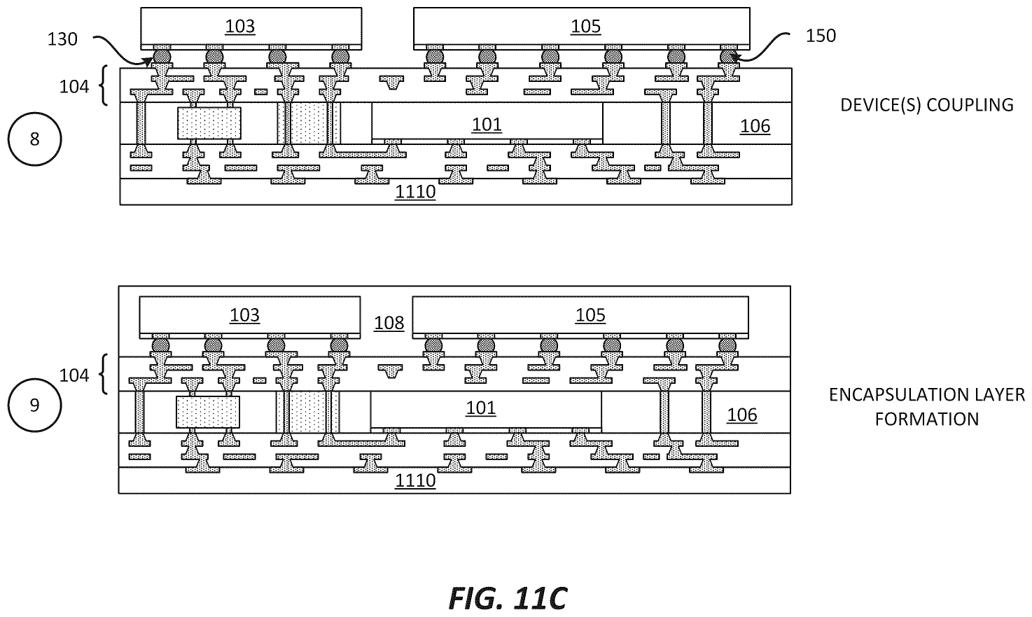

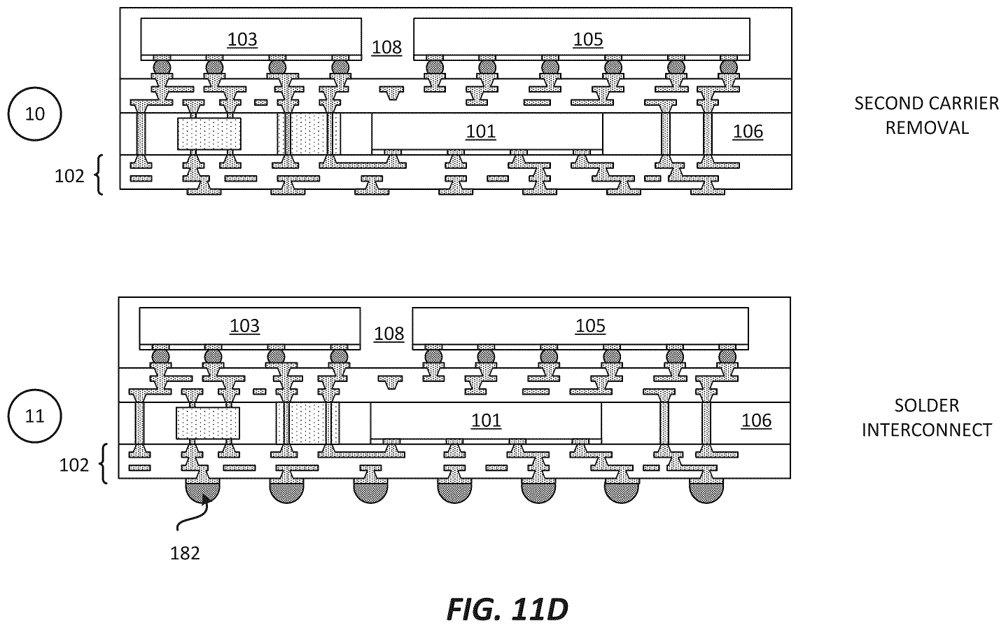

In some implementations, fabricating a package includes several processes. FIGS. 11A-11D illustrate an exemplary sequence for providing or fabricating a package. In some implementations, the sequence of FIGS. 11A-11D may be used to provide or fabricate the package 100. However, the process of FIGS. 11A-11D may be used to fabricate any of the packages described in the disclosure.

It should be noted that the sequence of FIGS. 11A-11D may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 11A, illustrates a state after a plurality of post interconnects 162 are formed on a carrier 1100. The carrier 1100 may be a first carrier. The plurality of post interconnects 162 may include different heights. A plating process may be used to form the plurality of post interconnects 162.

Stage 2 illustrates a state after an integrated device 101, a bridge 107 and a passive component 109 are coupled to the carrier 1100. A pick and place process may be used to the integrated device 101, the bridge 107 and the passive component 109 to the carrier 1100. In some implementations, an adhesive may be used to couple the back side of the integrated device 101 and/or the bridge 107 to the carrier 1100. The passive component 109 may be coupled to some post interconnects from the plurality of post interconnects 162.

Stage 3 illustrates a state after an encapsulation layer 106 is formed and coupled to the carrier 1100, the integrated device 101, the bridge 107 and the passive component 109. The encapsulation layer 106 may at least partially encapsulate the integrated device 101, the bridge 107, the passive component 109 and the plurality of post interconnects 162. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

Stage 4, as shown in FIG. 11B, illustrates a state after a metallization portion 102 is formed and coupled to the encapsulation layer 106, the integrated device 101, the bridge 107, the passive component 109 and the plurality of post interconnects 162. The metallization portion 102 includes at least one dielectric layer 120 and a plurality of metallization interconnects 122. The plurality of metallization interconnects 122 may include a plurality of redistribution interconnects. The plurality of metallization interconnects 122 may be coupled to the integrated device 101, the bridge 107, the passive component 109 and/or the plurality of post interconnects 162.

Stage 5 illustrates a state after the carrier 1100 is decoupled from the encapsulation layer 106, the integrated device 101, the bridge 107, the passive component 109, and the plurality of post interconnects 162. The carrier 1100 may be detached and/or peeled off from the encapsulation layer 106, the integrated device 101, the bridge 107, the passive component 109, and the plurality of post interconnects 162.

Stage 6 illustrates a state after a carrier 1110 is coupled to the metallization portion 102. The carrier 1110 may be a second carrier. The carrier 1110 may include an adhesive.

Stage 7 illustrates a state after a metallization portion 104 is formed and coupled to the encapsulation layer 106, the integrated device 101, the bridge 107, the passive component 109 and the plurality of post interconnects 162. The metallization portion 104 includes at least one dielectric layer 140 and a plurality of metallization interconnects 142. The plurality of metallization interconnects 142 may include a plurality of redistribution interconnects. The plurality of metallization interconnects 142 may be coupled to the integrated device 101, the bridge 107, the passive component 109 and/or the plurality of post interconnects 162. The encapsulation layer 106, the integrated device 101, the bridge 107, the passive component 109 and the plurality of post interconnects 162 may be located between the metallization portion 102 and the metallization portion 104.

Stage 8, as shown in FIG. 11C, illustrates a state after an integrated device 103 is coupled to the metallization portion 104 through a plurality of solder interconnects 130. Stage 8 also illustrates a state after an integrated device 105 is coupled to the metallization portion 104 through a plurality of solder interconnects 150. One or more solder reflow process may be used to couple the integrated device 103 and/or the integrated device 105 to the metallization portion 104 through a plurality of solder interconnects.

Stage 9 illustrates a state after an encapsulation layer 108 is formed and coupled to the metallization portion 104, the integrated device 103 and the integrated device 105. The encapsulation layer 108 may at least partially encapsulate the integrated device 103 and the integrated device 105. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

Stage 10, as shown in FIG. 11D, illustrates a state after the carrier 1110 is decoupled from the metallization portion 102. The carrier 1110 may be a second carrier. The carrier 1110 may be detached and/or peeled off from the metallization portion 102.

Stage 11 illustrates a state after a plurality of solder interconnects 182 are coupled to the metallization portion 102 through a solder reflow process. The plurality of solder interconnects 182 may be coupled to the plurality of metallization interconnects 122. Stage 11 may illustrate a package 100 that includes two metallization portions and a bridge located between the two metallization portions.

### Exemplary Sequence for Fabricating a Package Comprising a Bridge Between Metallization Portions

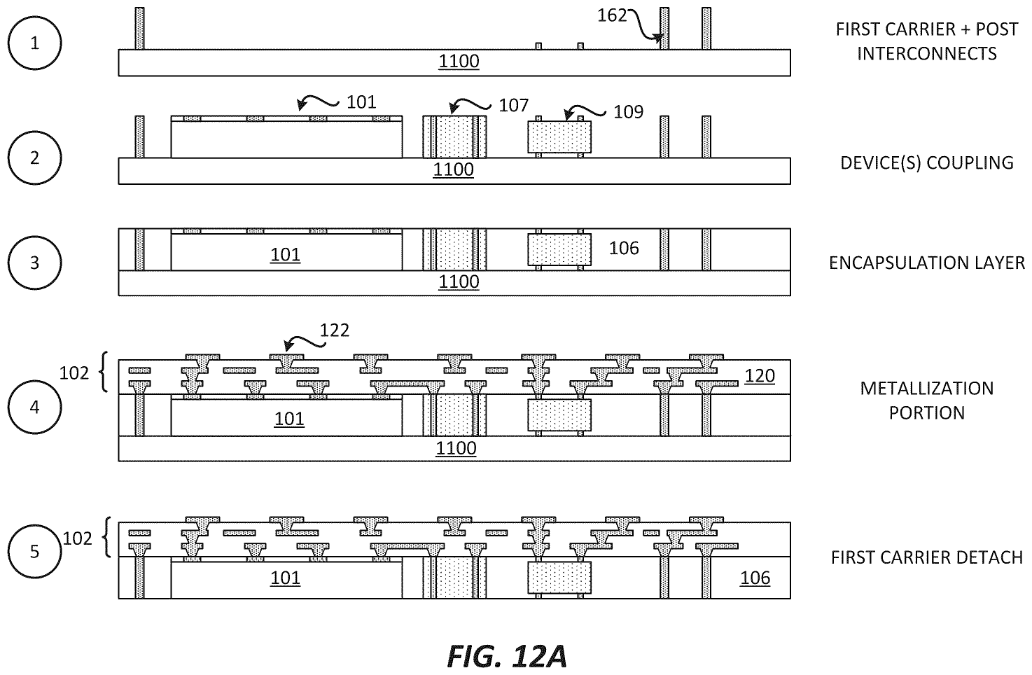

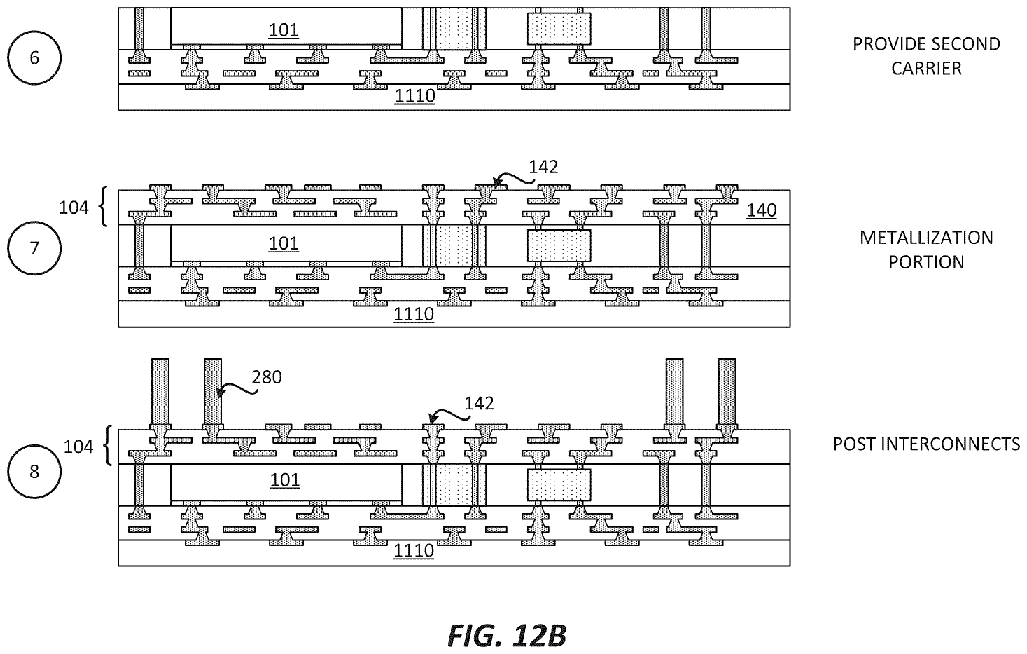

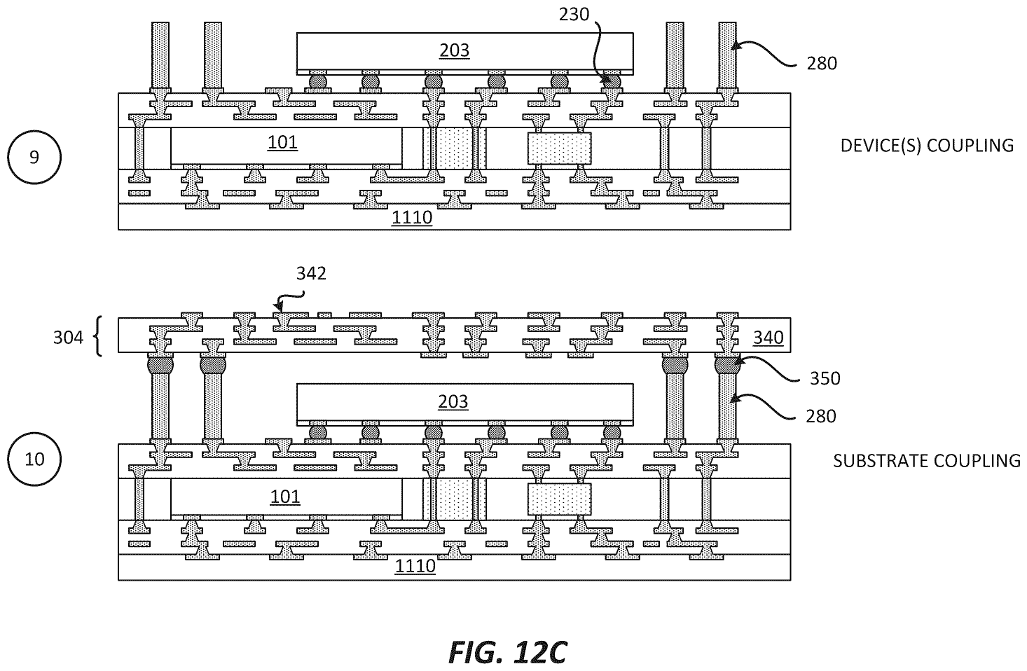

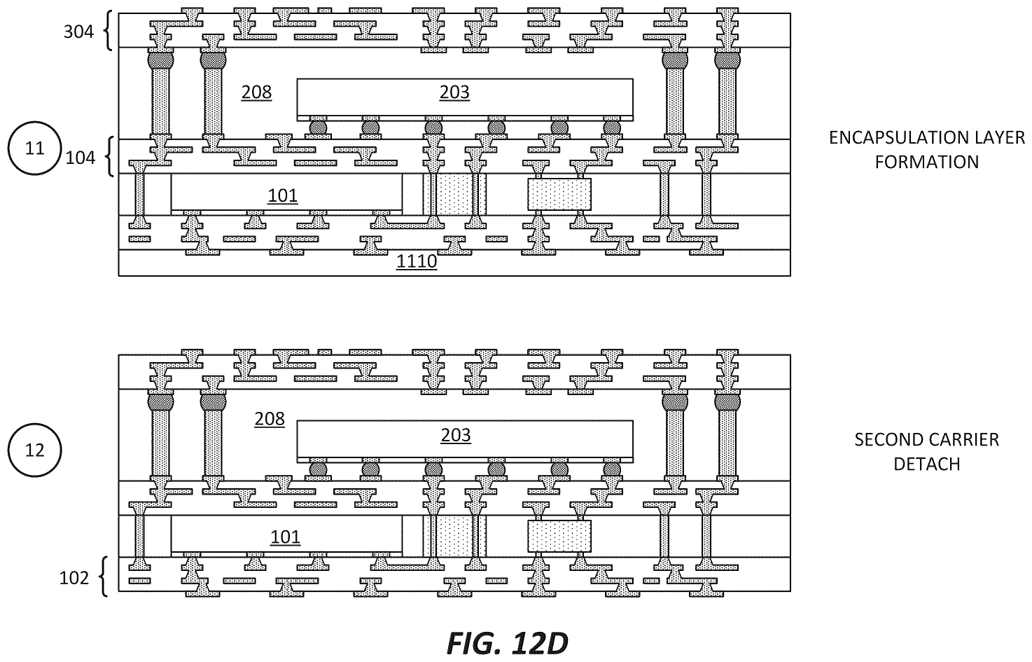

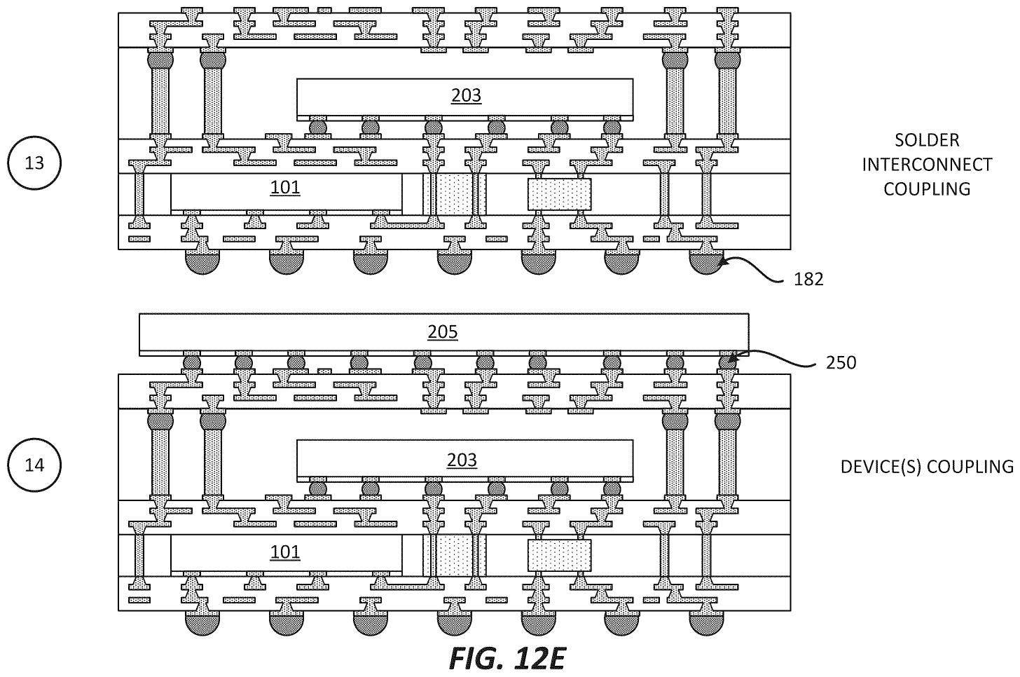

In some implementations, fabricating a package includes several processes. FIGS. 12A-12E illustrate an exemplary sequence for providing or fabricating a package. In some implementations, the sequence of FIGS. 12A-12E may be used to provide or fabricate the package 300. However, the process of FIGS. 12A-12E may be used to fabricate any of the packages described in the disclosure.

It should be noted that the sequence of FIGS. 12A-12E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 12A, illustrates a state after a plurality of post interconnects 162 are formed on a carrier 1100. The carrier 1100 may be a first carrier. The plurality of post interconnects 162 may include different heights. A plating process may be used to form the plurality of post interconnects 162.

Stage 2 illustrates a state after an integrated device 101, a bridge 107 and a passive component 109 are coupled to the carrier 1100. A pick and place process may be used to the integrated device 101, the bridge 107 and the passive component 109 to the carrier 1100. In some implementations, an adhesive may be used to couple the back side of the integrated device 101 and/or the bridge 107 to the carrier 1100. The passive component 109 may be coupled to some post interconnects from the plurality of post interconnects 162.

Stage 3 illustrates a state after an encapsulation layer 106 is formed and coupled to the carrier 1100, the integrated device 101, the bridge 107 and the passive component 109. The encapsulation layer 106 may at least partially encapsulate the integrated device 101, the bridge 107, the passive component 109 and the plurality of post interconnects 162. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

Stage 4 illustrates a state after a metallization portion 102 is formed and coupled to the encapsulation layer 106, the integrated device 101, the bridge 107, the passive component 109 and the plurality of post interconnects 162. The metallization portion 102 includes at least one dielectric layer 120 and a plurality of metallization interconnects 122. The plurality of metallization interconnects 122 may include a plurality of redistribution interconnects. The plurality of metallization interconnects 122 may be coupled to the integrated device 101, the bridge 107, the passive component 109 and/or the plurality of post interconnects 162.

Stage 5 illustrates a state after the carrier 1100 is decoupled from the encapsulation layer 106, the integrated device 101, the bridge 107, the passive component 109, and the plurality of post interconnects 162. The carrier 1100 may be detached and/or peeled off from the encapsulation layer 106, the integrated device 101, the bridge 107, the passive component 109, and the plurality of post interconnects 162.

Stage 6, as shown in FIG. 12B, illustrates a state after a carrier 1110 is coupled to the metallization portion 102. The carrier 1110 may be a second carrier. The carrier 1110 may include an adhesive.

Stage 7 illustrates a state after a metallization portion 104 is formed and coupled to the encapsulation layer 106, the integrated device 101, the bridge 107, the passive component 109 and the plurality of post interconnects 162. The metallization portion 104 includes at least one dielectric layer 140 and a plurality of metallization interconnects 142. The plurality of metallization interconnects 142 may include a plurality of redistribution interconnects. The plurality of metallization interconnects 142 may be coupled to the integrated device 101, the bridge 107, the passive component 109 and/or the plurality of post interconnects 162. The encapsulation layer 106, the integrated device 101, the bridge 107, the passive component 109 and the plurality of post interconnects 162 may be located between the metallization portion 102 and the metallization portion 104.

Stage 8 illustrates a state after a plurality of post interconnects 280 are formed and coupled to the metallization portion 104. The plurality of post interconnects 280 may be coupled to the plurality of metallization interconnects 142. A plating process may be used to form the plurality of post interconnects 280.

Stage 9, as shown in FIG. 12C, illustrates a state after an integrated device 203 is coupled to the metallization portion 104 through a plurality of solder interconnects 230. A solder reflow process may be used to couple the integrated device 203 to the metallization portion 104 through a plurality of solder interconnects.

Stage 10 illustrates a state after a substrate 304 is coupled to the plurality of post interconnects 280 through a plurality of solder interconnects 350. A solder reflow process may be used to couple the substrate 304 to the plurality of post interconnects 280. The substrate 304 may be a laminate substrate. The substrate 304 includes at least one dielectric layer 340 and a plurality of interconnects 342. The plurality of solder interconnects 350 may be coupled to the plurality of interconnects 342 and the plurality of post interconnects 280.

Stage 11, as shown in FIG. 12D, illustrates a state after an encapsulation layer 208 is formed and coupled to the metallization portion 104, the integrated device 203 and the substrate 304. The encapsulation layer 208 may at least partially encapsulate the integrated device 203. The encapsulation layer 208 may be located between the metallization portion 104 and the substrate 304. The encapsulation layer 208 may include a mold, a resin and/or an epoxy. The encapsulation layer 208 may be a means for encapsulation. The encapsulation layer 208 may be provided by using a compression and transfer molding process, a sheet molding process, or a liquid molding process.

Stage 12 illustrates a state after the carrier 1110 is decoupled from the metallization portion 102. The carrier 1110 may be a second carrier. The carrier 1110 may be detached and/or peeled off from the metallization portion 102.

Stage 13, as shown in FIG. 12E, illustrates a state after a plurality of solder interconnects 182 are coupled to the metallization portion 102 through a solder reflow process. The plurality of solder interconnects 182 may be coupled to the plurality of metallization interconnects 122.

Stage 14 illustrates a state after the integrated device 205 is coupled to the substrate 304 through a plurality of solder interconnects 250. A solder reflow process may be used to couple the integrated device 205 to the substrate 304. Stage 14 may illustrate a package 300 that includes a substrate, two metallization portions and a bridge located between the two metallization portions.

### Exemplary Sequence for Fabricating a Package Comprising a Bridge Between Metallization Portions

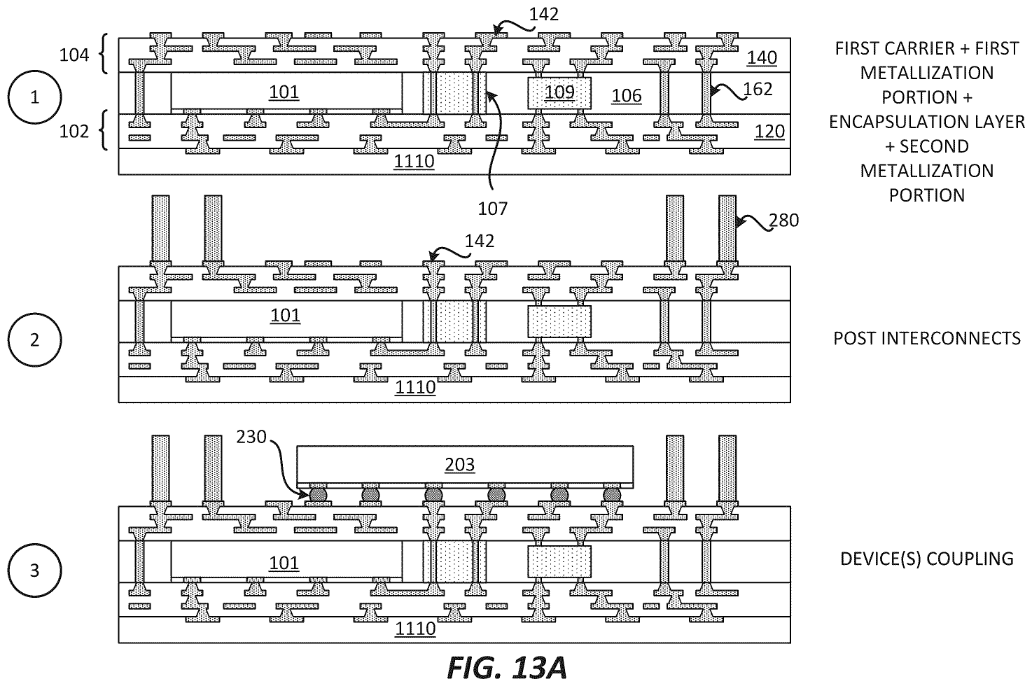

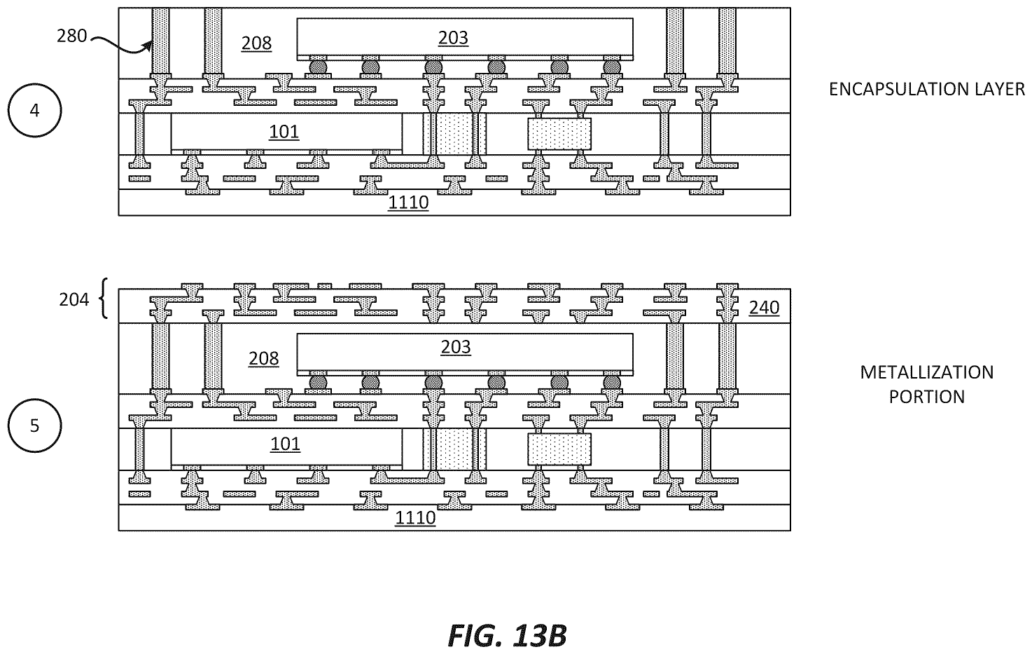

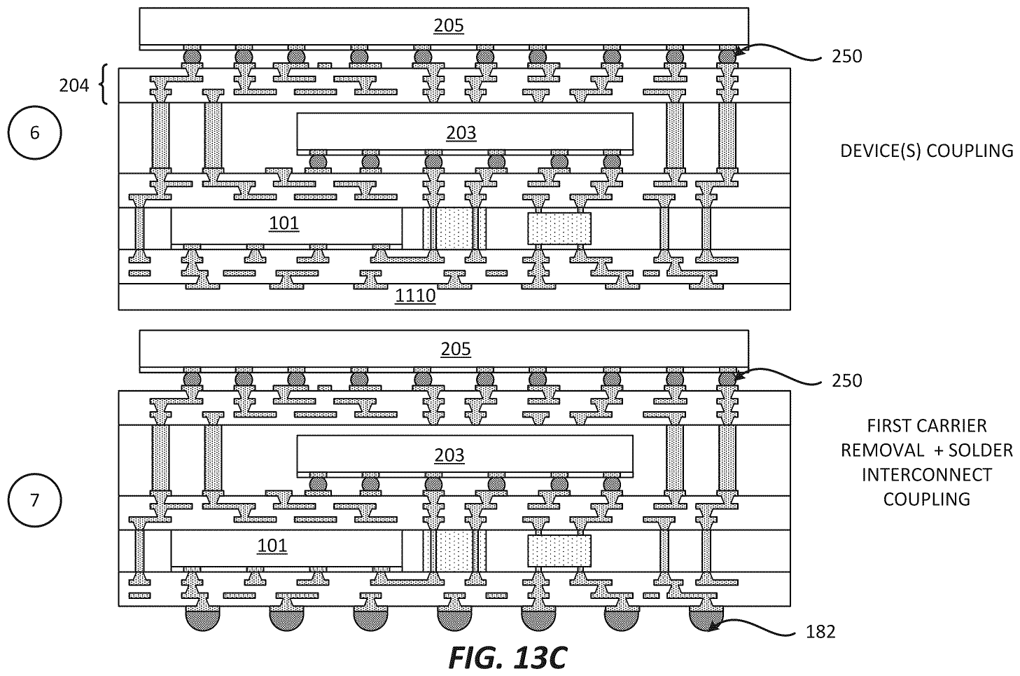

In some implementations, fabricating a package includes several processes. FIGS. 13A-13C illustrate an exemplary sequence for providing or fabricating a package. In some implementations, the sequence of FIGS. 13A-13C may be used to provide or fabricate the package 200. However, the process of FIGS. 13A-13C may be used to fabricate any of the packages described in the disclosure.

It should be noted that the sequence of FIGS. 13A-13C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 13A, illustrates a state after providing and/or fabricating a carrier 1110, a metallization portion 102, an integrated device 101, a bridge 107, a passive component 109, a plurality of post interconnects 162, an encapsulation layer 106 and a metallization portion 104. Stage 1 of FIG. 12A through stage 7 of FIG. 12B, may illustrate and describe an example of providing and/or fabricating a carrier 1110, a metallization portion 102, an integrated device 101, a bridge 107, a passive component 109, a plurality of post interconnects 162, an encapsulation layer 106 and a metallization portion 104.

Stage 2 illustrates a state after a plurality of post interconnects 280 are formed and coupled to the metallization portion 104. The plurality of post interconnects 280 may be coupled to the plurality of metallization interconnects 142. A plating process may be used to form the plurality of post interconnects 280.

Stage 3 illustrates a state after an integrated device 203 is coupled to the metallization portion 104 through a plurality of solder interconnects 230. A solder reflow process may be used to couple the integrated device 203 to the metallization portion 104 through a plurality of solder interconnects.

Stage 4, as shown in FIG. 13B, illustrates a state after an encapsulation layer 208 is formed and coupled to the metallization portion 104, the integrated device 203 and the plurality of post interconnects 280. The encapsulation layer 208 may at least partially encapsulate the integrated device 203 and the plurality of post interconnects 280. The encapsulation layer 208 may include a mold, a resin and/or an epoxy. The encapsulation layer 208 may be a means for encapsulation. The encapsulation layer 208 may be provided by using a compression and transfer molding process, a sheet molding process, or a liquid molding process.

Stage 5 illustrates a state after a metallization portion 204 is formed and coupled to the encapsulation layer 208, the integrated device 203 and the plurality of post interconnects 280. The metallization portion 204 includes at least one dielectric layer 240 and a plurality of metallization interconnects 242. The plurality of metallization interconnects 242 may include a plurality of redistribution interconnects. The plurality of metallization interconnects 242 may be coupled to the plurality of post interconnects 280. The encapsulation layer 208, the integrated device 203 and the plurality of post interconnects 280 may be located between the metallization portion 104 and the metallization portion 204.

Stage 6, as shown in FIG. 13C, illustrates a state after the integrated device 205 is coupled to the metallization portion 204 through a plurality of solder interconnects 250. A solder reflow process may be used to couple the integrated device 205 to the metallization portion 204.

Stage 7 illustrates a state after the carrier 1110 is decoupled from the metallization portion 102. The carrier 1110 may be a second carrier. The carrier 1110 may be detached and/or peeled off from the metallization portion 102.

Stage 7 also illustrates a state after a plurality of solder interconnects 182 are coupled to the metallization portion 102 through a solder reflow process. The plurality of solder interconnects 182 may be coupled to the plurality of metallization interconnects 122. Stage 7 may illustrate a package 200 that includes three metallization portions and a bridge located between the two of the three metallization portions.

### Exemplary Flow Diagram of a Method for Fabricating a Package Comprising a Bridge Between Metallization Portions

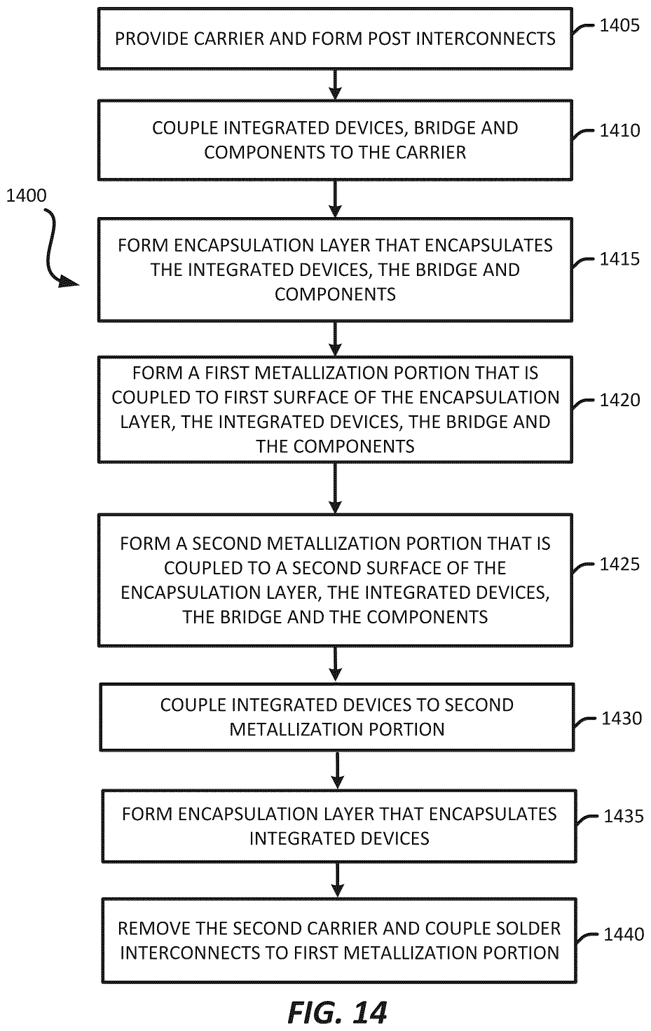

In some implementations, fabricating a package includes several processes. FIG. 14 illustrates an exemplary flow diagram of a method 1400 for providing or fabricating a package. In some implementations, the method 1400 of FIG. 14 may be used to provide or fabricate the package 100 described in the disclosure. However, the method 1400 may be used to provide or fabricate any of the packages described in the disclosure.

It should be noted that the method 1400 of FIG. 14 may combine one or more processes in order to simplify and/or clarify the method for providing or fabricating a package. In some implementations, the order of the processes may be changed or modified.

The method provides (at 1405) a carrier and form a plurality of post interconnects. Stage 1 of FIG. 11A, illustrates a state after a plurality of post interconnects 162 are formed on a carrier 1100. The carrier 1100 may be a first carrier. The plurality of post interconnects 162 may include different heights. A plating process may be used to form the plurality of post interconnects 162.

The method couples (at 1410) integrated devices, a bridge and/or other components to the carrier. Stage 2 of FIG. 11A, illustrates a state after an integrated device 101, a bridge 107 and a passive component 109 are coupled to the carrier 1100. A pick and place process may be used to the integrated device 101, the bridge 107 and the passive component 109 to the carrier 1100. In some implementations, an adhesive may be used to couple the back side of the integrated device 101 and/or the bridge 107 to the carrier 1100. The passive component 109 may be coupled to some post interconnects from the plurality of post interconnects 162.

The method forms (at 1415) an encapsulation layer. Stage 3 of FIG. 11A, illustrates a state after an encapsulation layer 106 is formed and coupled to the carrier 1100, the integrated device 101, the bridge 107 and the passive component 109. The encapsulation layer 106 may at least partially encapsulate the integrated device 101, the bridge 107, the passive component 109 and the plurality of post interconnects 162. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

The method forms (at 1420) a first metallization portion. Stage 4 of FIG. 11B, illustrates a state after a metallization portion 102 is formed and coupled to the encapsulation layer 106, the integrated device 101, the bridge 107, the passive component 109 and the plurality of post interconnects 162. The metallization portion 102 includes at least one dielectric layer 120 and a plurality of metallization interconnects 122. The plurality of metallization interconnects 122 may include a plurality of redistribution interconnects. The plurality of metallization interconnects 122 may be coupled to the integrated device 101, the bridge 107, the passive component 109 and/or the plurality of post interconnects 162.

After forming the first metallization portion, a carrier may be decoupled and another carrier may be coupled to the first metallization portion. Stage 5 of FIG. 11B, illustrates a state after the carrier 1100 is decoupled from the encapsulation layer 106, the integrated device 101, the bridge 107, the passive component 109, and the plurality of post interconnects 162. The carrier 1100 may be detached and/or peeled off from the encapsulation layer 106, the integrated device 101, the bridge 107, the passive component 109, and the plurality of post interconnects 162.

Stage 6 of FIG. 11B, illustrates a state after a carrier 1110 is coupled to the metallization portion 102. The carrier 1110 may be a second carrier. The carrier 1110 may include an adhesive.

The method forms (at 1425) a second metallization portion. Stage 7 of FIG. 11B, illustrates a state after a metallization portion 104 is formed and coupled to the encapsulation layer 106, the integrated device 101, the bridge 107, the passive component 109 and the plurality of post interconnects 162. The metallization portion 104 includes at least one dielectric layer 140 and a plurality of metallization interconnects 142. The plurality of metallization interconnects 142 may include a plurality of redistribution interconnects. The plurality of metallization interconnects 142 may be coupled to the integrated device 101, the bridge 107, the passive component 109 and/or the plurality of post interconnects 162. The encapsulation layer 106, the integrated device 101, the bridge 107, the passive component 109 and the plurality of post interconnects 162 may be located between the metallization portion 102 and the metallization portion 104.

The method couples (at 1430) integrated devices to the second metallization portion. Stage 8 of FIG. 11C, illustrates a state after an integrated device 103 is coupled to the metallization portion 104 through a plurality of solder interconnects 130. Stage 8 also illustrates a state after an integrated device 105 is coupled to the metallization portion 104 through a plurality of solder interconnects 150. One or more solder reflow process may be used to couple the integrated device 103 and/or the integrated device 105 to the metallization portion 104 through a plurality of solder interconnects.

The method forms (at 1435) another encapsulation layer. Stage 9 of FIG. 11C, illustrates a state after an encapsulation layer 108 is formed and coupled to the metallization portion 104, the integrated device 103 and the integrated device 105. The encapsulation layer 108 may at least partially encapsulate the integrated device 103 and the integrated device 105. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The method decouples (at 1440) the second carrier and couples (at 1440) a plurality of solder interconnects to the first metallization portion. Stage 10 of FIG. 11D, illustrates a state after the carrier 1110 is decoupled from the metallization portion 102. The carrier 1110 may be a second carrier. The carrier 1110 may be detached and/or peeled off from the metallization portion 102.

Stage 11 of FIG. 11D, illustrates a state after a plurality of solder interconnects 182 are coupled to the metallization portion 102 through a solder reflow process. The plurality of solder interconnects 182 may be coupled to the plurality of metallization interconnects 122. Stage 11 may illustrate a package 100 that includes two metallization portions and a bridge located between the two metallization portions.

In some implementations, several packages are fabricated at the same time. In such cases, the method may singulate the package.

Exemplary Sequence for Fabricating a Package Comprising a Bridge Between Metallization Portions

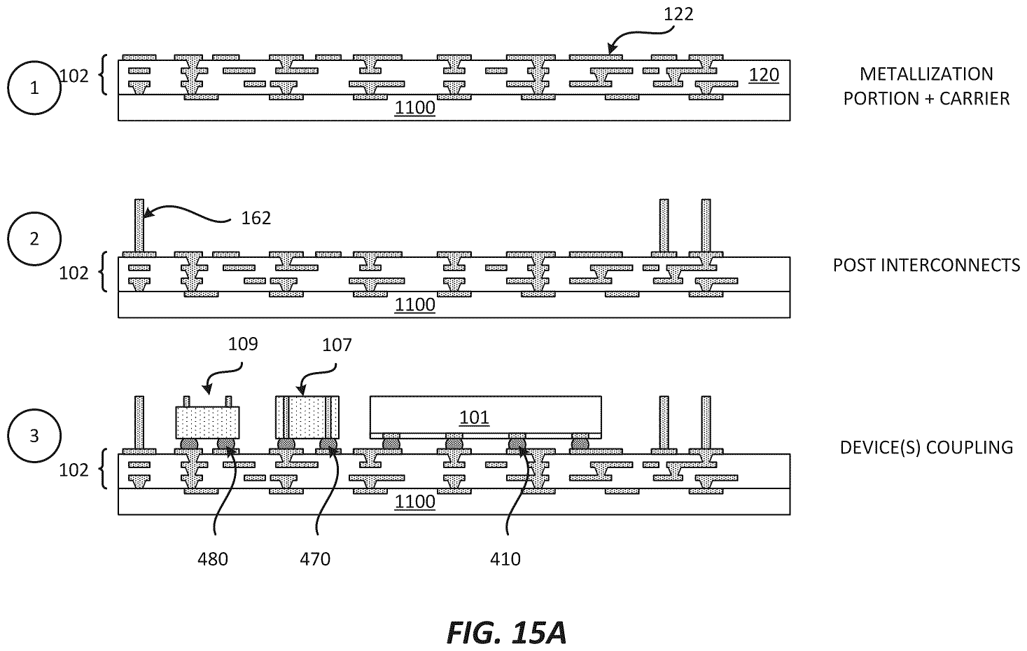

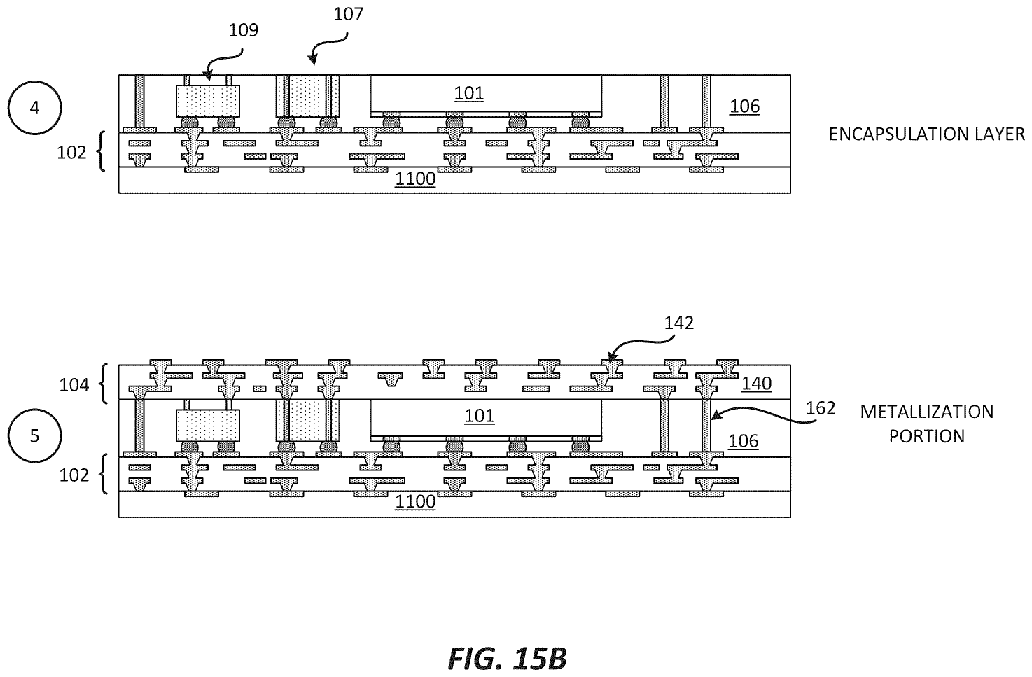

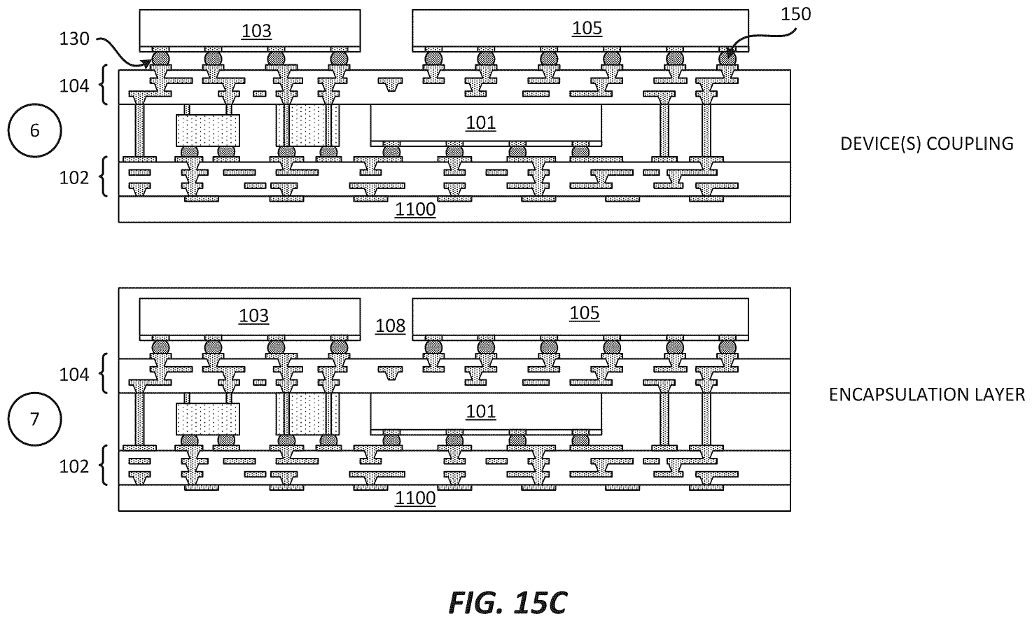

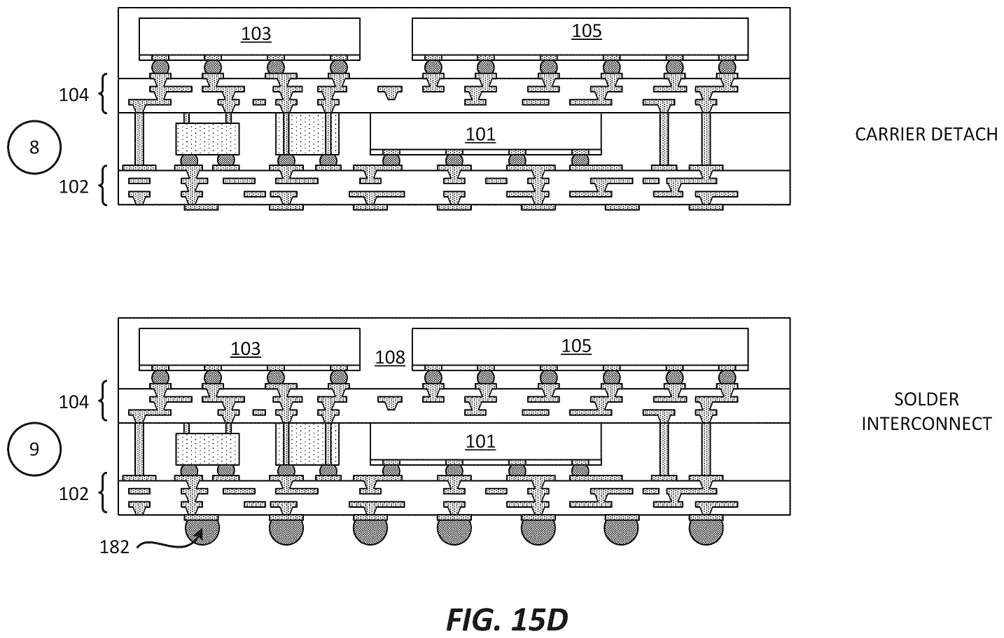

In some implementations, fabricating a package includes several processes. FIGS. 15A-15D illustrate an exemplary sequence for providing or fabricating a package. In some implementations, the sequence of FIGS. 15A-15D may be used to provide or fabricate the package 400. However, the process of FIGS. 15A-15D may be used to fabricate any of the packages described in the disclosure.

It should be noted that the sequence of FIGS. 15A-15D may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 15A, illustrates a state after a carrier 1100 and a metallization portion 102 are provided and/or formed. The metallization portion 102 includes at least one dielectric layer 120 and a plurality of metallization interconnects 122. The metallization portion 102 may be coupled to the carrier 1100.

Stage 2 illustrates a state after a plurality of post interconnects 162 are formed on the metallization portion 102. The plurality of post interconnects 162 may be coupled to the plurality of metallization interconnects 122. A plating process may be used to form the plurality of post interconnects 162.

Stage 3 illustrates a state after an integrated device 101, a bridge 107 and a passive component 109 are coupled to the metallization portion 102 through a plurality of solder interconnects. A solder reflow process may be used to couple the integrated device 101, the bridge 107 and the passive component 109 to the metallization portion 102. The integrated device 101 is coupled to the metallization portion 102 through a plurality of solder interconnects 410. The bridge 107 may be coupled to the metallization portion 102 through a plurality of solder interconnects 470. The passive component 109 may be coupled to the metallization portion 102 through a plurality of solder interconnects 480.

Stage 4, as shown in FIG. 15B, illustrates a state after an encapsulation layer 106 is formed and coupled to the metallization portion 102, the integrated device 101, the bridge 107 and the passive component 109. The encapsulation layer 106 may at least partially encapsulate the integrated device 101, the bridge 107, the passive component 109 and the plurality of post interconnects 162. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

Stage 5 illustrates a state after a metallization portion 104 is formed and coupled to the encapsulation layer 106, the integrated device 101, the bridge 107, the passive component 109 and the plurality of post interconnects 162. The metallization portion 104 includes at least one dielectric layer 140 and a plurality of metallization interconnects 142. The plurality of metallization interconnects 142 may include a plurality of redistribution interconnects. The plurality of metallization interconnects 142 may be coupled to the integrated device 101, the bridge 107, the passive component 109 and/or the plurality of post interconnects 162. The encapsulation layer 106, the integrated device 101, the bridge 107, the passive component 109 and the plurality of post interconnects 162 may be located between the metallization portion 102 and the metallization portion 104.

Stage 6, as shown in FIG. 15C, illustrates a state after an integrated device 103 is coupled to the metallization portion 104 through a plurality of solder interconnects 130. Stage 6 also illustrates a state after an integrated device 105 is coupled to the metallization portion 104 through a plurality of solder interconnects 150. One or more solder reflow process may be used to couple the integrated device 103 and/or the integrated device 105 to the metallization portion 104 through a plurality of solder interconnects.

Stage 7 illustrates a state after an encapsulation layer 108 is formed and coupled to the metallization portion 104, the integrated device 103 and the integrated device 105. The encapsulation layer 108 may at least partially encapsulate the integrated device 103 and the integrated device 105. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

Stage 8, as shown in FIG. 15D, illustrates a state after the carrier 1110 is decoupled from the metallization portion 102. The carrier 1110 may be a second carrier. The carrier 1110 may be detached and/or peeled off from the metallization portion 102.

Stage 9 illustrates a state after a plurality of solder interconnects 182 are coupled to the metallization portion 102 through a solder reflow process. The plurality of solder interconnects 182 may be coupled to the plurality of metallization interconnects 122. Stage 9 may illustrate a package 400 that includes two metallization portions and a bridge located between the two metallization portions.

Exemplary Sequence for Fabricating a Package Comprising a Bridge Between Metallization Portions

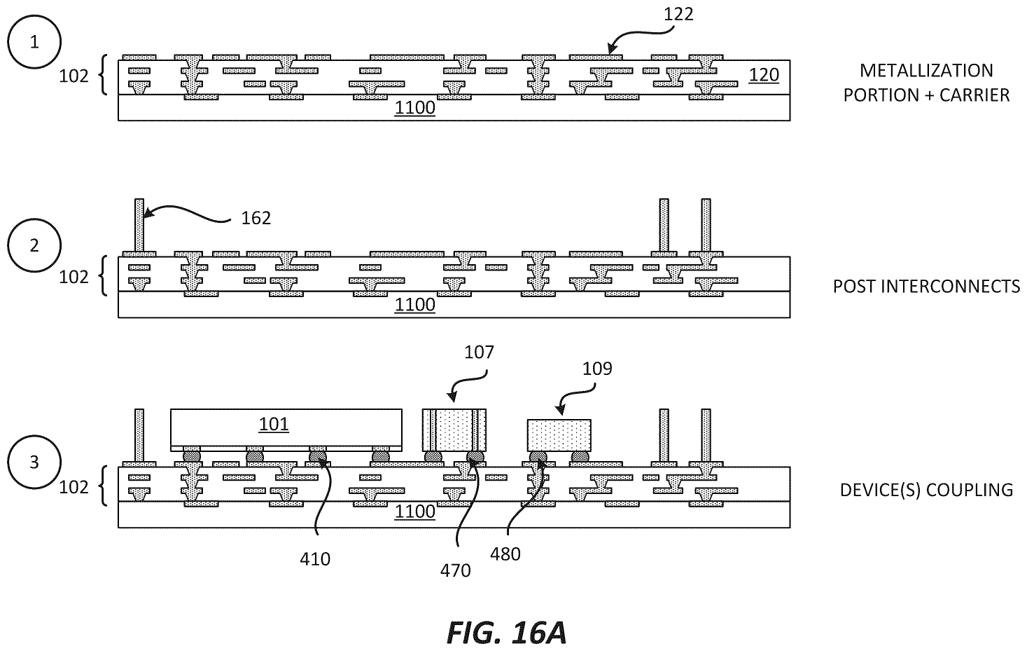

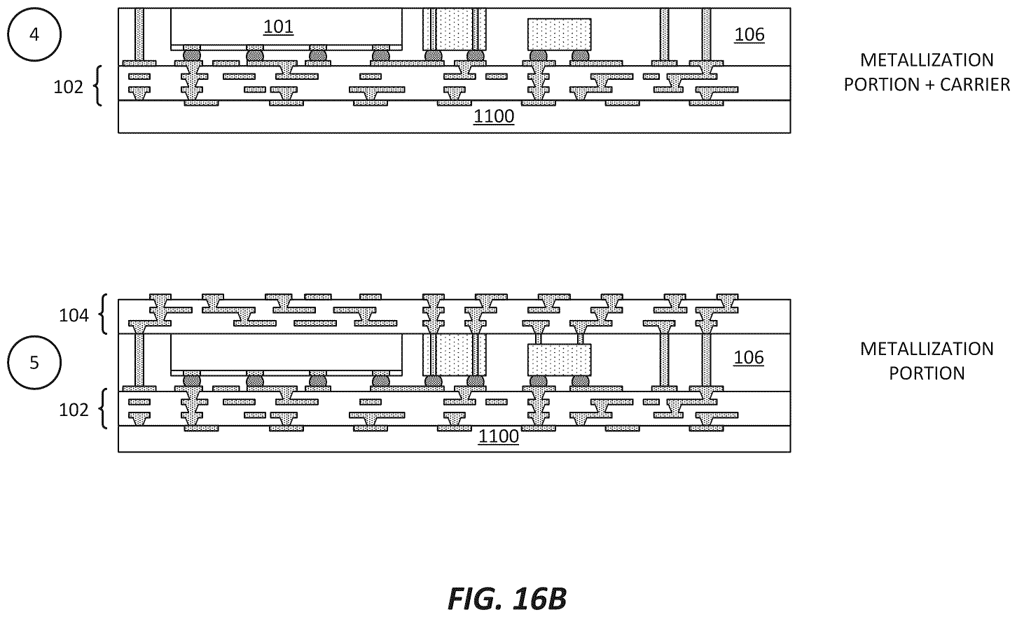

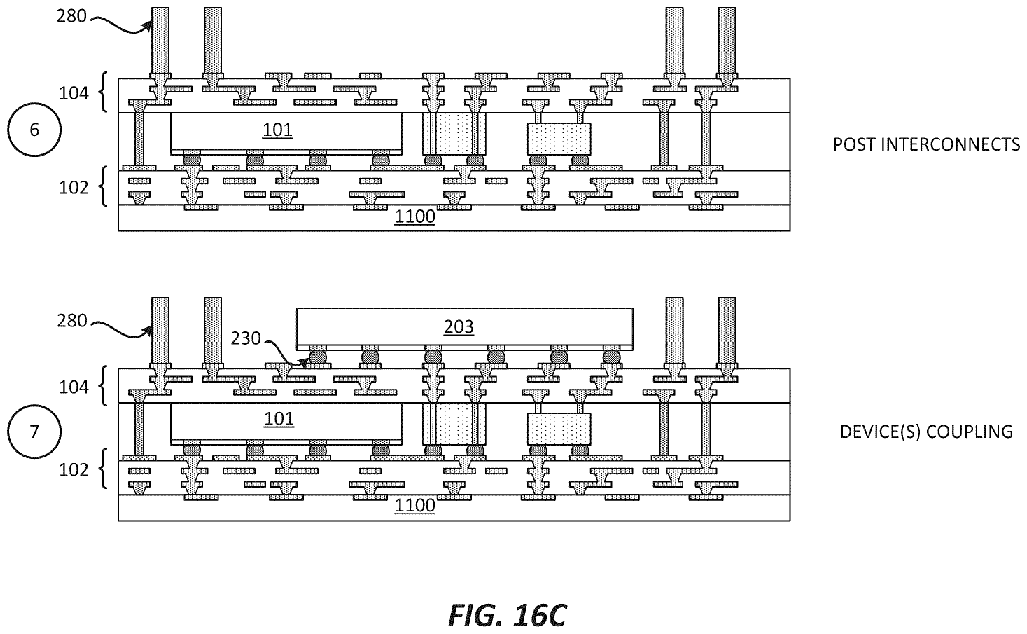

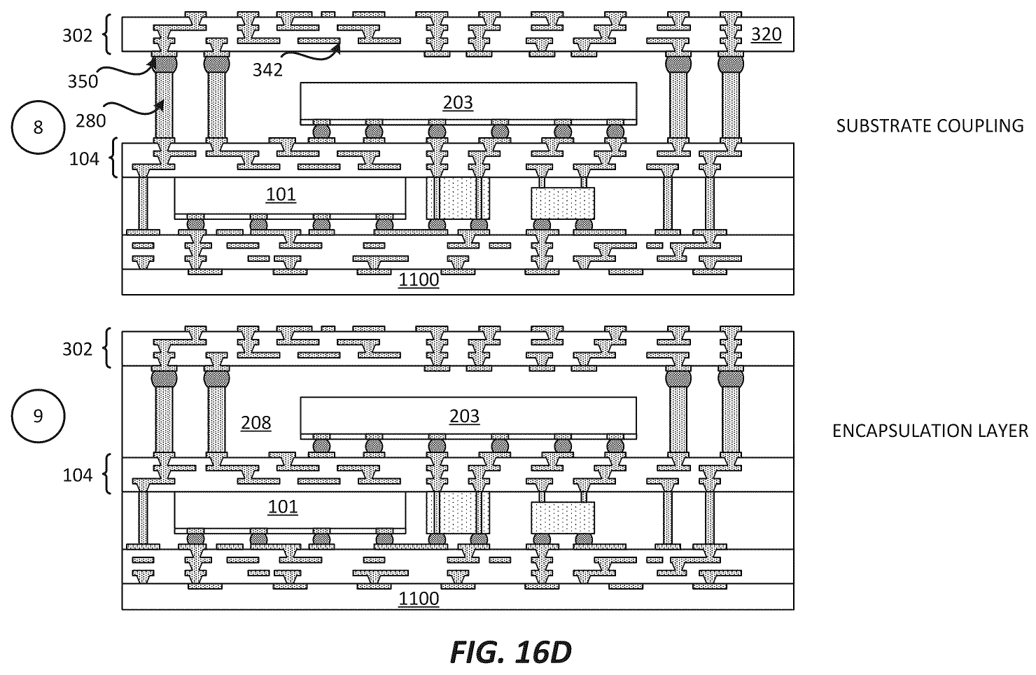

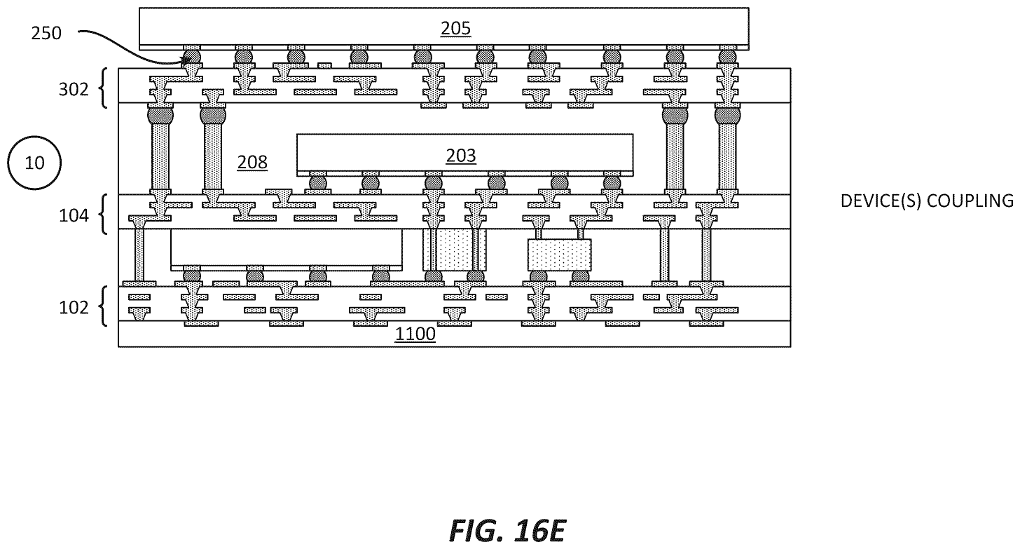

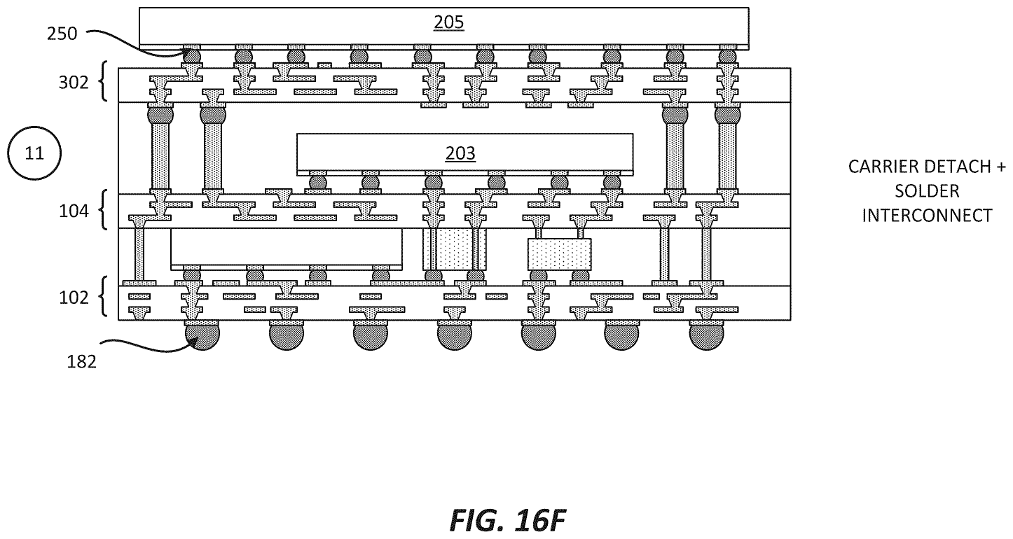

In some implementations, fabricating a package includes several processes. FIGS. 16A-16F illustrate an exemplary sequence for providing or fabricating a package. In some implementations, the sequence of FIGS. 16A-16F may be used to provide or fabricate the package 400. However, the process of FIGS. 16A-16F may be used to fabricate any of the packages described in the disclosure.

It should be noted that the sequence of FIGS. 16A-16F may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 16A, illustrates a state after a carrier 1100 and a metallization portion 102 are provided and/or formed. The metallization portion 102 includes at least one dielectric layer 120 and a plurality of metallization interconnects 122. The metallization portion 102 may be coupled to the carrier 1100.

Stage 2 illustrates a state after a plurality of post interconnects 162 are formed on the metallization portion 102. The plurality of post interconnects 162 may be coupled to the plurality of metallization interconnects 122. A plating process may be used to form the plurality of post interconnects 162.

Stage 3 illustrates a state after an integrated device 101, a bridge 107 and a passive component 109 are coupled to the metallization portion 102 through a plurality of solder interconnects. A solder reflow process may be used to couple the integrated device 101, the bridge 107 and the passive component 109 to the metallization portion 102. The integrated device 101 is coupled to the metallization portion 102 through a plurality of solder interconnects 410. The bridge 107 may be coupled to the metallization portion 102 through a plurality of solder interconnects 470. The passive component 109 may be coupled to the metallization portion 102 through a plurality of solder interconnects 480.

Stage 4, as shown in FIG. 16B, illustrates a state after an encapsulation layer 106 is formed and coupled to the metallization portion 102, the integrated device 101, the bridge 107 and the passive component 109. The encapsulation layer 106 may at least partially encapsulate the integrated device 101, the bridge 107, the passive component 109 and the plurality of post interconnects 162. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

Stage 5 illustrates a state after a metallization portion 104 is formed and coupled to the encapsulation layer 106, the integrated device 101, the bridge 107, the passive component 109 and the plurality of post interconnects 162. The metallization portion 104 includes at least one dielectric layer 140 and a plurality of metallization interconnects 142. The plurality of metallization interconnects 142 may include a plurality of redistribution interconnects. The plurality of metallization interconnects 142 may be coupled to the integrated device 101, the bridge 107, the passive component 109 and/or the plurality of post interconnects 162. The encapsulation layer 106, the integrated device 101, the bridge 107, the passive component 109 and the plurality of post interconnects 162 may be located between the metallization portion 102 and the metallization portion 104.

Stage 6, as shown in FIG. 16C, illustrates a state after a plurality of post interconnects 280 are formed and coupled to the metallization portion 104. The plurality of post interconnects 280 may be coupled to the plurality of metallization interconnects 142. A plating process may be used to form the plurality of post interconnects 280.

Stage 7 illustrates a state after an integrated device 203 is coupled to the metallization portion 104 through a plurality of solder interconnects 230. A solder reflow process may be used to couple the integrated device 203 to the metallization portion 104 through a plurality of solder interconnects.

Stage 8, as shown in FIG. 16D, illustrates a state after a substrate 304 is coupled to the plurality of post interconnects 280 through a plurality of solder interconnects 350. A solder reflow process may be used to couple the substrate 304 to the plurality of post interconnects 280. The substrate 304 may be a laminate substrate. The substrate 304 includes at least one dielectric layer 340 and a plurality of interconnects 342. The plurality of solder interconnects 350 may be coupled to the plurality of interconnects 342 and the plurality of post interconnects 280.

Stage 9 illustrates a state after an encapsulation layer 208 is formed and coupled to the metallization portion 104, the integrated device 203 and the substrate 304. The encapsulation layer 208 may at least partially encapsulate the integrated device 203. The encapsulation layer 208 may be located between the metallization portion 104 and the substrate 304. The encapsulation layer 208 may include a mold, a resin and/or an epoxy. The encapsulation layer 208 may be a means for encapsulation. The encapsulation layer 208 may be provided by using a compression and transfer molding process, a sheet molding process, or a liquid molding process.

Stage 10, as shown in FIG. 16E, illustrates a state after the integrated device 205 is coupled to the substrate 304 through a plurality of solder interconnects 250. A solder reflow process may be used to couple the integrated device 205 to the substrate 304. Stage 14 may illustrate a package 300 that includes a substrate, two metallization portions and a bridge located between the two metallization portions.

Stage 11 illustrates a state after the carrier 1110 is decoupled from the metallization portion 102. The carrier 1110 may be a second carrier. The carrier 1110 may be detached and/or peeled off from the metallization portion 102.

Stage 11 also illustrates a state after a plurality of solder interconnects 182 are coupled to the metallization portion 102 through a solder reflow process. The plurality of solder interconnects 182 may be coupled to the plurality of metallization interconnects 122.

Exemplary Sequence for Fabricating a Package Comprising a Bridge Between Metallization Portions

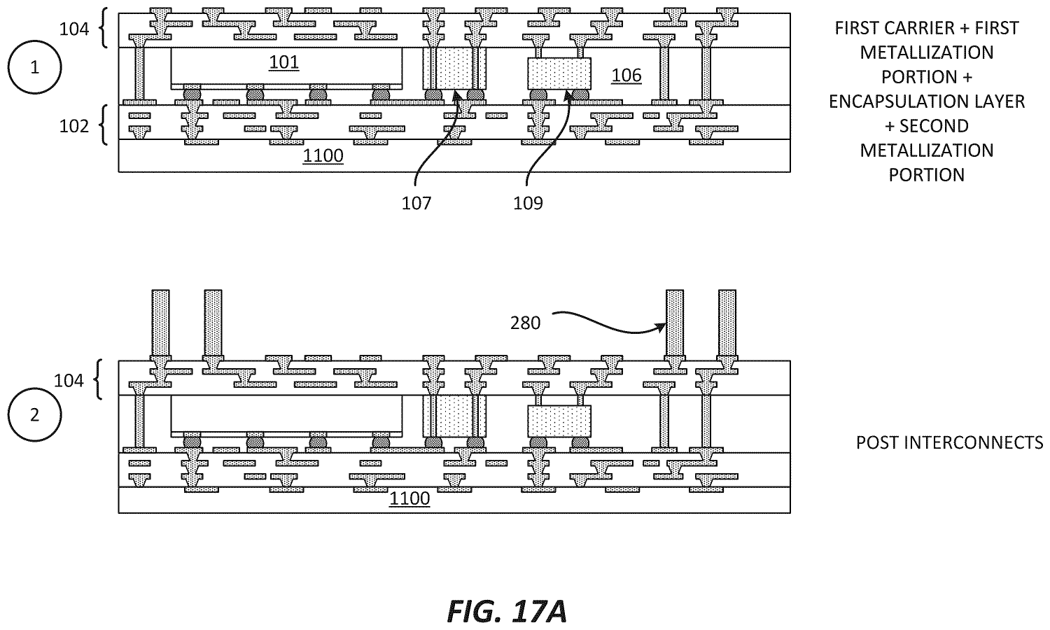

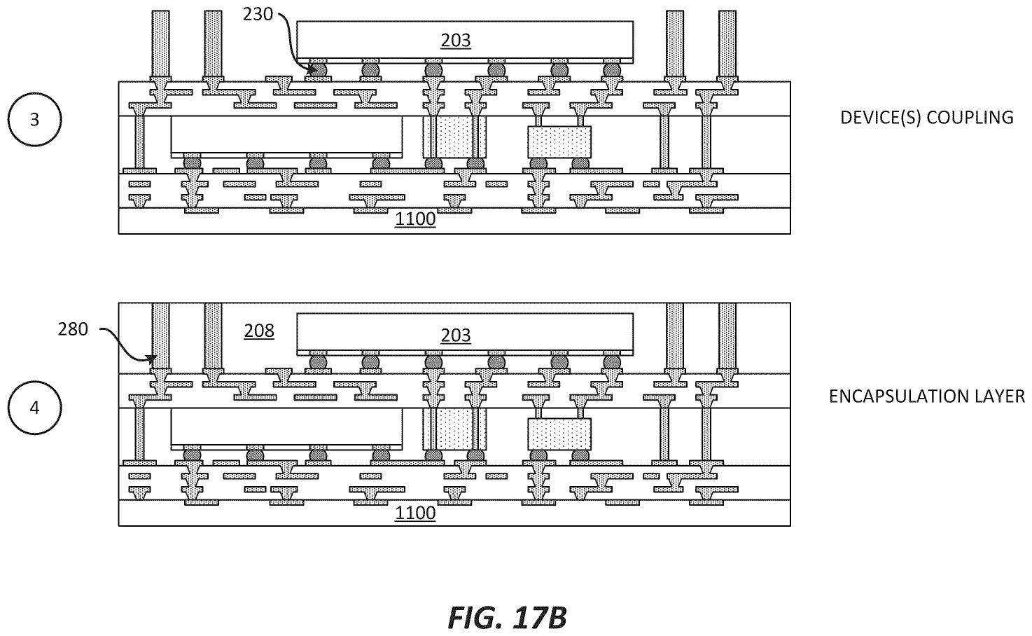

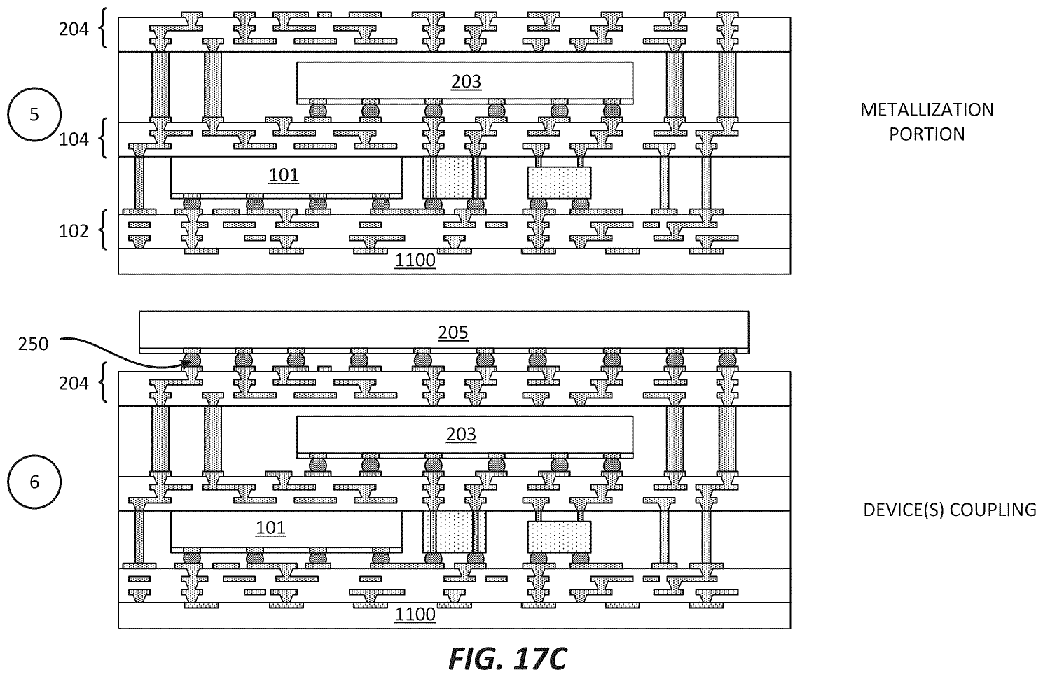

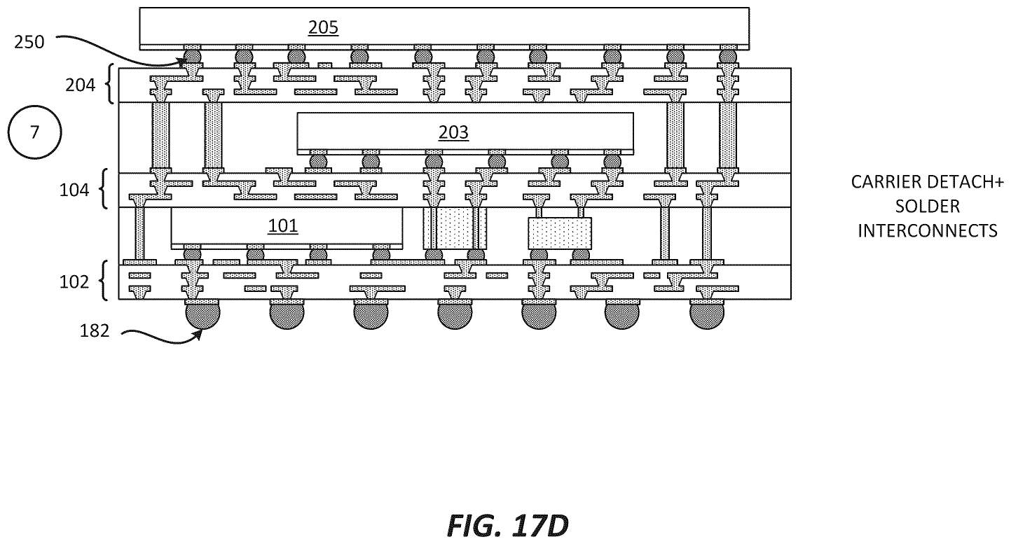

In some implementations, fabricating a package includes several processes. FIGS. 17A-17D illustrate an exemplary sequence for providing or fabricating a package. In some implementations, the sequence of FIGS. 17A-17D may be used to provide or fabricate the package 500. However, the process of FIGS. 17A-17D may be used to fabricate any of the packages described in the disclosure.

It should be noted that the sequence of FIGS. 17A-17D may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 17A, illustrates a state after providing and/or fabricating a carrier 1110, a metallization portion 102, an integrated device 101, a bridge 107, a passive component 109, a plurality of post interconnects 162, an encapsulation layer 106 and a metallization portion 104. Stage 1 of FIG. 16A through stage 5 of FIG. 16B, may illustrate and describe an example of providing and/or fabricating a carrier 1100, a metallization portion 102, an integrated device 101, a bridge 107, a passive component 109, a plurality of post interconnects 162, an encapsulation layer 106 and a metallization portion 104.

Stage 2 illustrates a state after a plurality of post interconnects 280 are formed and coupled to the metallization portion 104. The plurality of post interconnects 280 may be coupled to the plurality of metallization interconnects 142. A plating process may be used to form the plurality of post interconnects 280.

Stage 3, as shown in FIG. 17B, illustrates a state after an integrated device 203 is coupled to the metallization portion 104 through a plurality of solder interconnects 230. A solder reflow process may be used to couple the integrated device 203 to the metallization portion 104 through a plurality of solder interconnects.

Stage 4 illustrates a state after an encapsulation layer 208 is formed and coupled to the metallization portion 104, the integrated device 203 and the plurality of post interconnects 280. The encapsulation layer 208 may at least partially encapsulate the integrated device 203 and the plurality of post interconnects 280. The encapsulation layer 208 may include a mold, a resin and/or an epoxy. The encapsulation layer 208 may be a means for encapsulation. The encapsulation layer 208 may be provided by using a compression and transfer molding process, a sheet molding process, or a liquid molding process.

Stage 5, as shown in FIG. 17C, illustrates a state after a metallization portion 204 is formed and coupled to the encapsulation layer 208, the integrated device 203 and the plurality of post interconnects 280. The metallization portion 204 includes at least one dielectric layer 240 and a plurality of metallization interconnects 242. The plurality of metallization interconnects 242 may include a plurality of redistribution interconnects. The plurality of metallization interconnects 242 may be coupled to the plurality of post interconnects 280. The encapsulation layer 208, the integrated device 203 and the plurality of post interconnects 280 may be located between the metallization portion 104 and the metallization portion 204.

Stage 6 illustrates a state after the integrated device 205 is coupled to the metallization portion 204 through a plurality of solder interconnects 250. A solder reflow process may be used to couple the integrated device 205 to the metallization portion 204.

Stage 7, as shown in FIG. 17D, illustrates a state after the carrier 1100 is decoupled from the metallization portion 102. The carrier 1100 may be a second carrier. The carrier 1100 may be detached and/or peeled off from the metallization portion 102.

Stage 7 also illustrates a state after a plurality of solder interconnects 182 are coupled to the metallization portion 102 through a solder reflow process. The plurality of solder interconnects 182 may be coupled to the plurality of metallization interconnects 122. Stage 7 may illustrate a package 500 that includes, three metallization portions and a bridge located between the two of the three metallization portions.

### Exemplary Flow Diagram of a Method for Fabricating a Package Comprising a Bridge Between Metallization Portions

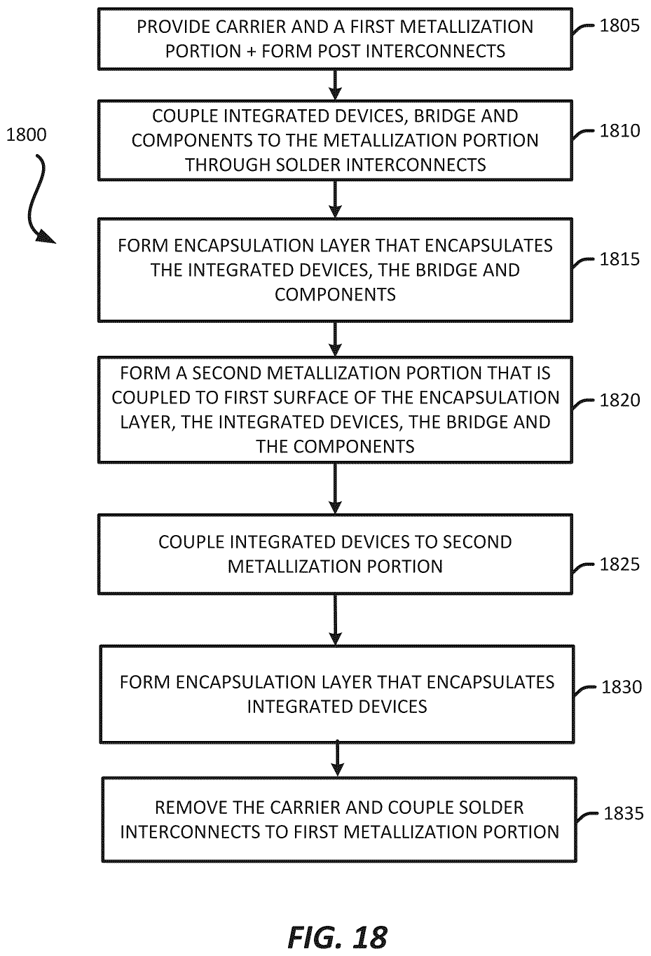

In some implementations, fabricating a package includes several processes. FIG. 18 illustrates an exemplary flow diagram of a method 1800 for providing or fabricating a package. In some implementations, the method 1800 of FIG. 18 may be used to provide or fabricate the package 400 described in the disclosure. However, the method 1800 may be used to provide or fabricate any of the packages described in the disclosure.

It should be noted that the method 1800 of FIG. 18 may combine one or more processes in order to simplify and/or clarify the method for providing or fabricating a package. In some implementations, the order of the processes may be changed or modified.

The method provides (at 1805) a carrier, a metallization portion and forms a plurality of post interconnects. Stage 1 of FIG. 15A, illustrates a state after a carrier 1100 and a metallization portion 102 are provided and/or formed. The metallization portion 102 includes at least one dielectric layer 120 and a plurality of metallization interconnects 122. The metallization portion 102 may be coupled to the carrier 1100.

Stage 2 of FIG. 15A. illustrates a state after a plurality of post interconnects 162 are formed on the metallization portion 102. The plurality of post interconnects 162 may be coupled to the plurality of metallization interconnects 122. A plating process may be used to form the plurality of post interconnects 162.

The method couples (at 1810) integrated devices, a bridge and/or other components to the first metallization portion. Stage 3 of FIG. 15A, illustrates a state after an integrated device 101, a bridge 107 and a passive component 109 are coupled to the metallization portion 102 through a plurality of solder interconnects. A solder reflow process may be used to couple the integrated device 101, the bridge 107 and the passive component 109 to the metallization portion 102. The integrated device 101 is coupled to the metallization portion 102 through a plurality of solder interconnects 410. The bridge 107 may be coupled to the metallization portion 102 through a plurality of solder interconnects 470. The passive component 109 may be coupled to the metallization portion 102 through a plurality of solder interconnects 480.

The method forms (at 1815) an encapsulation layer. Stage 4 of FIG. 15B, illustrates a state after an encapsulation layer 106 is formed and coupled to the metallization portion 102, the integrated device 101, the bridge 107 and the passive component 109. The encapsulation layer 106 may at least partially encapsulate the integrated device 101, the bridge 107, the passive component 109 and the plurality of post interconnects 162. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

The method forms (at 1820) a second metallization portion. Stage 5 of FIG. 15B, illustrates a state after a metallization portion 104 is formed and coupled to the encapsulation layer 106, the integrated device 101, the bridge 107, the passive component 109 and the plurality of post interconnects 162. The metallization portion 104 includes at least one dielectric layer 140 and a plurality of metallization interconnects 142. The plurality of metallization interconnects 142 may include a plurality of redistribution interconnects. The plurality of metallization interconnects 142 may be coupled to the integrated device 101, the bridge 107, the passive component 109 and/or the plurality of post interconnects 162. The encapsulation layer 106, the integrated device 101, the bridge 107, the passive component 109 and the plurality of post interconnects 162 may be located between the metallization portion 102 and the metallization portion 104.

The method couples (at 1825) integrated devices to the second metallization portion. Stage 6 of FIG. 15C, illustrates a state after an integrated device 103 is coupled to the metallization portion 104 through a plurality of solder interconnects 130. Stage 6 also illustrates a state after an integrated device 105 is coupled to the metallization portion 104 through a plurality of solder interconnects 150. One or more solder reflow process may be used to couple the integrated device 103 and/or the integrated device 105 to the metallization portion 104 through a plurality of solder interconnects.

The method forms (at 1830) an encapsulation layer. Stage 7 of FIG. 15C, illustrates a state after an encapsulation layer 108 is formed and coupled to the metallization portion 104, the integrated device 103 and the integrated device 105. The encapsulation layer 108 may at least partially encapsulate the integrated device 103 and the integrated device 105. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The method decouples (at 1835) the carrier and then couples (at 1835) a plurality of solder interconnects to the first metallization portion. Stage 8 of FIG. 15D, illustrates a state after the carrier 1110 is decoupled from the metallization portion 102. The carrier 1110 may be a second carrier. The carrier 1110 may be detached and/or peeled off from the metallization portion 102.

Stage 9 of FIG. 15D, illustrates a state after a plurality of solder interconnects 182 are coupled to the metallization portion 102 through a solder reflow process. The plurality of solder interconnects 182 may be coupled to the plurality of metallization interconnects 122. Stage 9 may illustrate a package 400 that includes two metallization portions and a bridge located between the two metallization portions.

In some implementations, several packages are fabricated at the same time. In such cases, the method may singulate the package.

### Exemplary Sequence for Fabricating a Metallization Portion

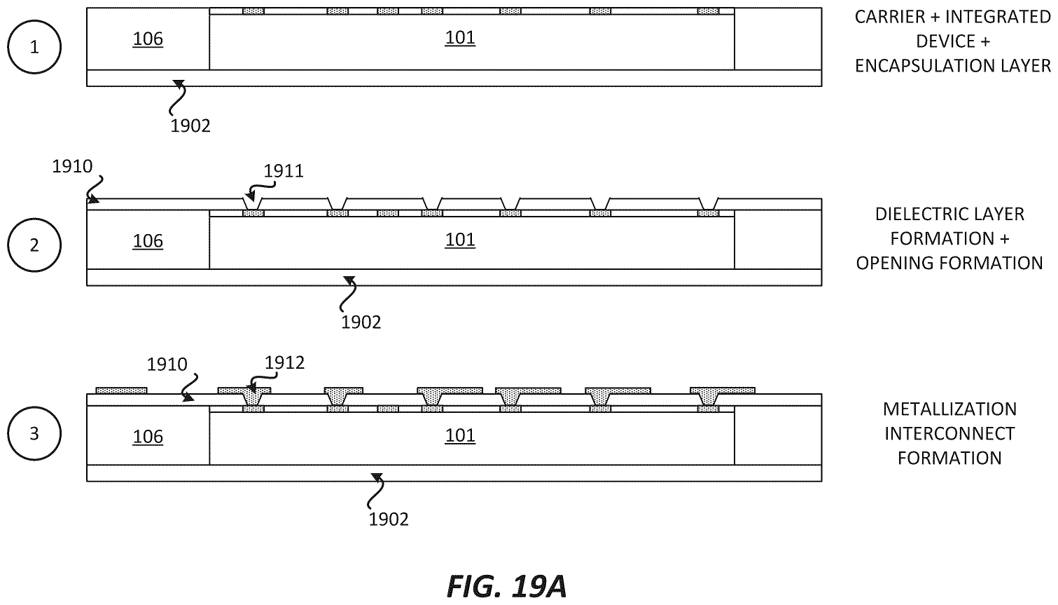

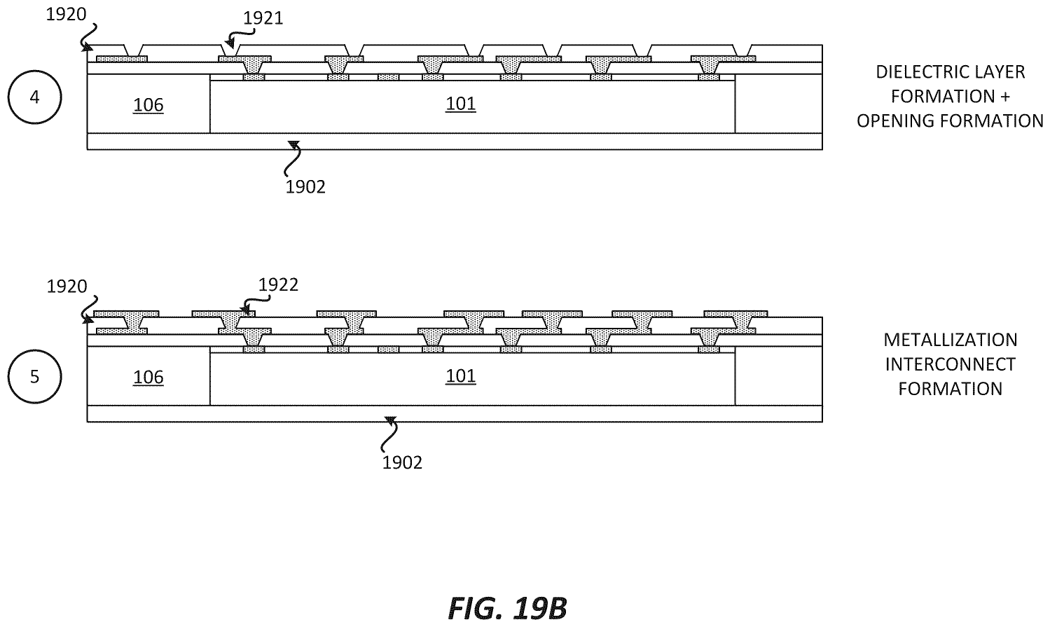

In some implementations, fabricating a metallization portion includes several processes. FIGS. 19A-19B illustrate an exemplary sequence for providing or fabricating a metallization portion. In some implementations, the sequence of FIGS. 19A-19B may be used to provide or fabricate the metallization portion 102. However, the process of FIGS. 19A-19B may be used to fabricate any of the metallization portions (e.g., 104, 204) described in the disclosure.

It should be noted that the sequence of FIGS. 19A-19B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 12A, illustrates a state after a carrier 1902, an integrated device 101 and an encapsulation layer 106 is provided and/or formed.

Stage 2 illustrates a state after a dielectric layer 1910 is formed over the integrated device 101 and the encapsulation layer 106. The dielectric layer 1910 may include a plurality of openings 1911. A deposition and/or lamination process may be used to form the dielectric layer 1910. The dielectric layer 1910 may include prepreg. The plurality of openings 1911 may be formed using an etching process (e.g., photo etching process) or laser process. For example, an exposure and development process may be used to form the plurality of openings 1911.

Stage 3 illustrates a state after a plurality of interconnects 1912 are formed in and over the dielectric layer 1910, including in and over the plurality of openings 1911. For example, via interconnects, pad interconnects and/or trace interconnects may be formed. A plating process may be used to form the interconnects. Stage 3 illustrates that some portions of the interconnects 1912 may have a U-shape or a V-shape. The terms “U-shape” and “V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect).

Stage 4, as shown in FIG. 19B, illustrates a state after a dielectric layer 1920 is formed over the dielectric layer 1910. The dielectric layer 1920 may include a plurality of openings 1921. A deposition and/or lamination process may be used to form the dielectric layer 1920. The dielectric layer 1920 may include prepreg. The plurality of openings 1921 may be formed using an etching process (e.g., photo etching process) or laser process. For example, an exposure and development process may be used to form the plurality of openings 1921.

Stage 5 illustrates a state after a plurality of interconnects 1922 are formed in and over the dielectric layer 1920, including in and over the plurality of openings 1921. For example, via interconnects, pad interconnects and/or trace interconnects may be formed. A plating process may be used to form the interconnects. Stage 5 illustrates that some portions of the interconnects 1922 may have a U-shape or a V-shape. The terms “U-shape” and “V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect).

It is noted that the process of forming the dielectric layers, the plurality of openings and the plurality of interconnects may be iteratively performed to form additional metal layers in the metallization portions.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

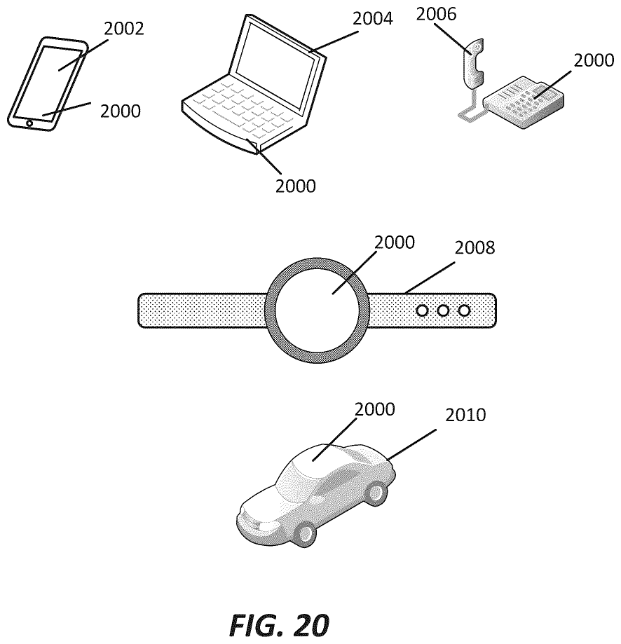

FIG. 20 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 2002, a laptop computer device 2004, a fixed location terminal device 2006, a wearable device 2008, or automotive vehicle 2010 may include a device 2000 as described herein. The device 2000 may be, for example, any of the devices and/or integrated circuit (IC) packages described herein. The devices 2002, 2004, 2006 and 2008 and the vehicle 2010 illustrated in FIG. 20 are merely exemplary. Other electronic devices may also feature the device 2000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-10, 11A-11D, 12A-12E, 13A-13C, 14, 15A-15D, 16A-16F, 17A-17D, 18, 19A-19B and 20 may be rearranged and/or combined into a single component, process, feature or function or embodied in several components, processes, or functions. Additional elements, components, processes, and/or functions may also be added without departing from the disclosure. It should also be noted FIGS. 1-10, 11A-11D, 12A-12E, 13A-13C, 14, 15A-15D, 16A-16F, 17A-17D, 18, 19A-19B and 20 and its corresponding description in the present disclosure is not limited to dies and/or ICs. In some implementations, FIGS. 1-10, 11A-11D, 12A-12E, 13A-13C, 14, 15A-15D, 16A-16F, 17A-17D, 18, 19A-19B and 20 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object that is coupled to another object may be coupled to at least part of the another object. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A package comprising a first metallization portion comprising: at least one first dielectric layer; and a first plurality of metallization interconnects; a first integrated device coupled to the first metallization portion; a bridge coupled to the first metallization portion; an encapsulation layer coupled to the first metallization portion; a second metallization portion coupled to the bridge and the encapsulation layer, such that the first integrated device, the bridge and the encapsulation layer are located between the first metallization portion and the second metallization portion, wherein the second metallization portion comprises: at least one second dielectric layer; and a second plurality of metallization interconnects; and a second integrated device coupled to the second metallization portion, wherein the second integrated device and the bridge at least partially vertically overlap.

Aspect 2: The package of aspect 1, wherein the bridge comprises: a silicon substrate; and a plurality of bridge interconnects.

Aspect 3: The package of aspects 1 through 2, wherein the first integrated device includes a first chiplet and the second integrated device includes a second chiplet.

Aspect 4: The package of aspects 1 through 3, wherein the first metallization portion includes a first redistribution portion, wherein the first plurality of metallization interconnects include a first plurality of redistribution interconnects, wherein the second metallization portion includes a second redistribution portion, and wherein the second plurality of metallization interconnects include a second plurality of redistribution interconnects.

Aspect 5: The package of aspects 1 through 4, further comprising a plurality of post interconnects located at least partially in the encapsulation layer.

Aspect 6: The package of aspects 1 through 5, wherein an electrical path between the first integrated device and the second integrated device includes the first metallization portion, the bridge and the second metallization portion.

Aspect 7: The package of aspects 1 through 6, wherein a bridge interconnect of the bridge is coupled to a metallization interconnect from the first metallization portion without any intervening solder interconnect.

Aspect 8: The package of aspects 1 through 7, wherein the first integrated device is coupled to a metallization interconnect from the first metallization portion without any intervening solder interconnect.

Aspect 9: The package of aspects 1 through 8, further comprising a second encapsulation layer coupled to the second metallization portion and the second integrated device.

Aspect 10: The package of aspect 9, further comprising a plurality of post interconnects located at least partially in the second encapsulation layer.

Aspect 11: The package of aspects 9 through 10, further comprising a third metallization portion coupled to the second encapsulation layer.

Aspect 12: The package of aspects 9 through 11, further comprising a substrate coupled to the second encapsulation layer.

Aspect 13: The package of aspect 12, wherein the substrate is coupled to a plurality of post interconnects through a plurality of solder interconnects.

Aspect 14: The package of aspects 12 through 13, further comprising a third integrated device coupled to the substrate.

Aspect 15: The package of aspects 1 through 14, further comprising a plurality of post interconnects located at least partially in the encapsulation layer, wherein the plurality of post interconnects comprise a first pitch, and wherein the bridge comprises a plurality of bridge interconnects comprising a second pitch that is less than the first pitch.

Aspect 16: The package of aspect 15, wherein the second pitch of the plurality of bridge interconnects is about 2-10 times smaller than the first pitch of the plurality of post interconnects.

Aspect 17: The package of aspects 1 through 16, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 18: A package comprising a first metallization portion comprising: at least one first dielectric layer; and a first plurality of metallization interconnects; a first integrated device coupled to the first metallization portion through at least a first plurality of solder interconnects; a bridge coupled to the first metallization portion through at least a second plurality of solder interconnects; an encapsulation layer coupled to the first metallization portion; a second metallization portion coupled to the bridge and the encapsulation layer, such that the first integrated device, the bridge and the encapsulation layer are located between the first metallization portion and the second metallization portion, wherein the second metallization portion comprises: at least one second dielectric layer; and a second plurality of metallization interconnects; and a second integrated device coupled to the second metallization portion through at least a third plurality of solder interconnects, wherein the second integrated device and the bridge at least partially vertically overlap.

Aspect 19: The package of aspect 18, wherein the bridge comprises: a silicon substrate; and a plurality of bridge interconnects.

Aspect 20: The package of aspects 18 through 19, wherein the first integrated device includes a first chiplet and the second integrated device includes a second chiplet.

Aspect 21: The package of aspects 18 through 20, wherein the first metallization portion includes a first redistribution portion, wherein the first plurality of metallization interconnects include a first plurality of redistribution interconnects, wherein the second metallization portion includes a second redistribution portion, and wherein the second plurality of metallization interconnects include a second plurality of redistribution interconnects.

Aspect 22: The package of aspects 18 through 21, further comprising a plurality of post interconnects located at least partially in the encapsulation layer.

Aspect 23: The package of aspects 18 through 22, wherein an electrical path between the first integrated device and the second integrated device includes a solder interconnect from the first plurality of solder interconnects, the first metallization portion, a solder interconnect from the second plurality of solder interconnects, the bridge, the second metallization portion and a solder interconnect from the third plurality of solder interconnects.

Aspect 24: The package of aspects 18 through 23, further comprising a second encapsulation layer coupled to the second metallization portion and the second integrated device.

Aspect 25: The package of aspect 24, further comprising a plurality of post interconnects located at least partially in the second encapsulation layer.

Aspect 26: The package of aspects 24 through 25, further comprising a third metallization portion coupled to the second encapsulation layer.

Aspect 27: The package of aspects 24 through 26, further comprising a substrate coupled to the second encapsulation layer.

Aspect 28: The package of aspect 27, further comprising a plurality of post interconnects located in the second encapsulation layer, wherein the substrate is coupled to the plurality of post interconnects through a fourth plurality of solder interconnects.

Aspect 29: The package of aspect 28, further comprising a third integrated device coupled to the substrate.

Aspect 30: The package of aspects 18 through 29, further comprising a plurality of post interconnects located at least partially in the encapsulation layer, wherein the plurality of post interconnects comprises a first pitch, and wherein the bridge comprises a plurality of bridge interconnects comprising a second pitch that is less than the first pitch.

Aspect 31: The package of aspect 30, wherein the second pitch of the plurality of bridge interconnects is about 2-10 times smaller than the first pitch of the plurality of post interconnects.

Aspect 32: The package of aspects 18 through 31, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first metallization portion comprising:
at least one first dielectric layer; and
a first plurality of metallization interconnects;
a first integrated device coupled to the first metallization portion;
a bridge coupled to the first metallization portion;
an encapsulation layer coupled to the first metallization portion;
a second metallization portion coupled to the bridge and the encapsulation layer, such that the first integrated device, the bridge and the encapsulation layer are located between the first metallization portion and the second metallization portion, wherein the second metallization portion comprises:
at least one second dielectric layer; and
a second plurality of metallization interconnects; and
a second integrated device coupled to the second metallization portion, wherein the second integrated device and the bridge at least partially vertically overlap.

2. The package of claim 1, wherein the bridge comprises:
a silicon substrate; and
a plurality of bridge interconnects.

3. The package of claim 1, wherein the first integrated device includes a first chiplet and the second integrated device includes a second chiplet.

4. The package of claim 1,
wherein the first metallization portion includes a first redistribution portion,
wherein the first plurality of metallization interconnects include a first plurality of redistribution interconnects,
wherein the second metallization portion includes a second redistribution portion, and
wherein the second plurality of metallization interconnects include a second plurality of redistribution interconnects.

5. The package of claim 1, further comprising a plurality of post interconnects located at least partially in the encapsulation layer.

6. The package of claim 1, wherein an electrical path between the first integrated device and the second integrated device includes the first metallization portion, the bridge and the second metallization portion.

7. The package of claim 1, wherein a bridge interconnect of the bridge is coupled to a metallization interconnect from the first metallization portion without any intervening solder interconnect.

8. The package of claim 1, wherein the first integrated device is coupled to a metallization interconnect from the first metallization portion without any intervening solder interconnect.

9. The package of claim 1, further comprising a second encapsulation layer coupled to the second metallization portion and the second integrated device.

10. The package of claim 9, further comprising a plurality of post interconnects located at least partially in the second encapsulation layer.

11. The package of claim 9, further comprising a third metallization portion coupled to the second encapsulation layer.

12. The package of claim 9, further comprising a substrate coupled to the second encapsulation layer.

13. The package of claim 12, wherein the substrate is coupled to a plurality of post interconnects through a plurality of solder interconnects.

14. The package of claim 12, further comprising a third integrated device coupled to the substrate.

15. The package of claim 1, further comprising a plurality of post interconnects located at least partially in the encapsulation layer,
wherein the plurality of post interconnects comprise a first pitch, and
wherein the bridge comprises a plurality of bridge interconnects comprising a second pitch that is less than the first pitch.

16. The package of claim 15, wherein the second pitch of the plurality of bridge interconnects is about 2-10 times smaller than the first pitch of the plurality of post interconnects.

17. The package of claim 1, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

18. A package comprising:
a first metallization portion comprising:
at least one first dielectric layer; and
a first plurality of metallization interconnects;
a first integrated device coupled to the first metallization portion through at least a first plurality of solder interconnects;
a bridge coupled to the first metallization portion through at least a second plurality of solder interconnects;
an encapsulation layer coupled to the first metallization portion;
a second metallization portion coupled to the bridge and the encapsulation layer, such that the first integrated device, the bridge and the encapsulation layer are located between the first metallization portion and the second metallization portion, wherein the second metallization portion comprises:
at least one second dielectric layer; and
a second plurality of metallization interconnects; and
a second integrated device coupled to the second metallization portion through at least a third plurality of solder interconnects, wherein the second integrated device and the bridge at least partially vertically overlap.

19. The package of claim 18, wherein the bridge comprises:
a silicon substrate; and
a plurality of bridge interconnects.

20. The package of claim 18, wherein the first integrated device includes a first chiplet and the second integrated device includes a second chiplet.

21. The package of claim 18,
wherein the first metallization portion includes a first redistribution portion,
wherein the first plurality of metallization interconnects include a first plurality of redistribution interconnects,
wherein the second metallization portion includes a second redistribution portion, and
wherein the second plurality of metallization interconnects include a second plurality of redistribution interconnects.

22. The package of claim 18, further comprising a plurality of post interconnects located at least partially in the encapsulation layer.

23. The package of claim 18, wherein an electrical path between the first integrated device and the second integrated device includes a solder interconnect from the first plurality of solder interconnects, the first metallization portion, a solder interconnect from the second plurality of solder interconnects, the bridge, the second metallization portion and a solder interconnect from the third plurality of solder interconnects.

24. The package of claim 18, further comprising a second encapsulation layer coupled to the second metallization portion and the second integrated device.

25. The package of claim 24, further comprising a plurality of post interconnects located at least partially in the second encapsulation layer.

26. The package of claim 24, further comprising a third metallization portion coupled to the second encapsulation layer.

27. The package of claim 24, further comprising a substrate coupled to the second encapsulation layer.

28. The package of claim 27, further comprising a plurality of post interconnects located in the second encapsulation layer, wherein the substrate is coupled to the plurality of post interconnects through a fourth plurality of solder interconnects.

29. The package of claim 28, further comprising a third integrated device coupled to the substrate.

30. The package of claim 18, further comprising a plurality of post interconnects located at least partially in the encapsulation layer,
wherein the plurality of post interconnects comprises a first pitch, and
wherein the bridge comprises a plurality of bridge interconnects comprising a second pitch that is less than the first pitch.

31. The package of claim 30, wherein the second pitch of the plurality of bridge interconnects is about 2-10 times smaller than the first pitch of the plurality of post interconnects.

32. The package of claim 18, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
